(19) United States
(12) Patent Application Publication
(10) Pub. No.: US 2012/0313129 A1
(43) Pub. Date: Dec. 13, 2012

(54) ORGANIC ELECTROLUMINESCENT ELEMENT, AND METHOD FOR MANUFACTURING ORGANIC ELECTROLUMINESCENT ELEMENT

(75) Inventors: Nobuyuki Zettsu, Suita-shi (JP); Yuji Kuwahara, Suita-shi (JP); Takafumi Uemura, Suita-shi (JP); Aya Fujiki, Suita-shi (JP); Takuya Tanaka, Suita-shi (JP); Megumi Akai, Suita-shi (JP)

(73) Assignee: OSAKA UNIVERSITY, Osaka (JP)

(21) Appl. No.: 13/511,302

(22) PCT Filed: Nov. 24, 2010
(86) PCT No.: PCT/JP2010/070882

§ 371 Date: Aug. 6, 2012

(30) Foreign Application Priority Data
Nov. 27, 2009 (JP) 2009-270714
May 25, 2010 (JP) 2010-119300

(51) Int. Cl. H01L 33/58

(52) U.S. Cl. 257/98; 438/29; 257/40; 257/E33.061

(57) ABSTRACT

An object of the present invention is to realize an OLED capable of attaining high luminescence luminance and easy to manufacture. An organic electroluminescence device (1) of the present invention includes a luminescent layer (7) between an anode (3) and a cathode (9). The luminescent layer (7) contains an organic luminescent material. The organic electroluminescence device includes: a hole transportation layer (6) formed between the anode (3) and the luminescent layer (7); a metal nano particle layer between the anode (3) and the hole transportation layer (6), the metal nano particle layer being a layer in which metal nano particles (5) are dispersedly distributed. The metal nano particle layer is such that gaps between the metal nano particles (5) dispersedly distributed are filled with a hole transportation material. The metal nano particles (5) causes resonance with excited electrons in the luminescent layer (7), thereby reinforcing the luminescence by surface plasmon.

### TECHNICAL FIELD

The present invention relates to an organic light-emitting device containing an organic luminescent material.

### BACKGROUND ART

Organic light-emitting devices (OLEDs) employing an organic EL (Electroluminescence) have advantages such as light in weight, small in thickness, flexible and drivable by a direct-current low-voltage driving. Moreover, OLEDs are practically employed in small-size display devices implemented on mobile phones etc., because OLEDs have excellent moving image display characteristics such as wide viewing angles and high contrasts. One example of promising practical applications for existing OLEDs is white-color illumination devices. Hurdles against practical uses of the OLEDs are to prolong their life and reduce production cost. So far, practical-level OLEDs have been developed by, for example, achieving a long life by developing new luminescent materials, using triplet luminescence by doping a phosphorescent material, implementing a lamination structure or a concentration-gradient structure, developing a multi-photon emission (tandem) element.

### CITATION LIST

### Non-Patent Literatures

Non-Patent Literature 1
K. Y. Yang, Kyung Cheol Choi, and C. W. Ahn, “Surface plasmon-enhanced spontaneous emission rate in an organic light-emitting device structure: cathode structure for plasmonic application”, Applied Physics letters, 2009, vol. 94, no. 17, 173301

Non-Patent Literature 2
Site of Eintesla Co. Ltd., [online], browsed on Dec. 24, 2008, Internet <URL: http://www.eintesla.om/products/dip/array.html>

Non-Patent Literature 3
Site of Gelest Inc. “Silanes”, [online], browsed on Jul. 16, 2009, Internet <URL: http://www.gelest.com/prod_list.asp?pltype=1&classtype=Silanes&currentpage=1>

Non-Patent Literature 4
Christy L. Haynes and Richard P. Van Duyne, “Nanosphere Lithography: A Versatile Nanofabrication Tool for Studies of Size-Dependent Nanoparticle Optics”, The Journal of Physical Chemistry B, 2001, 105 (24), pp. 5599-5611

Non-Patent Literature 5
Babak Nikoobakht and Mostafa A. El-Sayed, “Preparation and Growth Mechanism of Gold Nanorods(NRs) Using Seed-Mediated Growth Method”, Chemistry of Materials, 2003, 15 (10), pp 1957-1962

### SUMMARY OF INVENTION

### Technical Problem

However, OLEDs of low molecular type currently in practical use are produced by vapor-deposition techniques by using a low-molecular organic luminescent material. Layers (electron-injection layer, electron-transportation layer, luminescent layer, hole-transportation layer, charge generation layer, etc.) constituting the OLEDs of low-molecular type are formed by process mainly carried out under vacuum. Process under vacuum requires large-scale facility, and a manufacturing method mainly including such process under vacuum sets a limit in lowering cost and increasing an area of the OLEDs. Therefore, OLEDs of polymer type, in which an organic luminescent material of polymer type capable of forming the layers of OLEDs by coating is employed, have been researched.

The OLEDs of polymer type, however, are inferior to the OLEDs of low molecule in terms of luminescence luminance and length of life. Moreover, it is difficult for the OLEDs of polymer type by principle to adopt the triplet luminescence by doping the phosphorescent material and the concentration-gradient structure, which are employed in the OLEDs of low molecular type. This makes it difficult to improve the OLEDs of polymer type in terms of the luminescence luminance.

Moreover, in the OLEDs of low molecular type, the doping of the phosphorescent material has a difficulty in accurately adjusting doping material concentration. For accurate doping material concentration adjustment, a complicate process is necessary, thereby leading to cost increase. Moreover, excitation of phosphorescent luminescence takes a longer time to relax than that of fluorescent luminescence, so that the molecules are kept in the excitation state for a longer time, whereby the phosphorescent material is more highly chemically reactive, so that chemical reason of molecules of the luminescent layer likely take place to damage the molecules. This results in a short life of the OLEDs.

Non-Patent Literature 1 discloses an OLED of low molecular type, in which an electron-injection layer made from LiF and having a 1-nm thickness is formed on a cathode made from Al, and a small amount of Ag is deposited by vapor deposition on the electron-injection layer, and an electron-injection layer made from LiF and having a 1-nm thickness is formed thereon, and a luminescent layer made from Alq₃ is formed thereon. In this OLED, the Ag thin film partially and dispersedly formed between the electron-injection layers. This facilitates electron injection from the cathode, thereby improving the luminescence luminance of the OLED. According to description in Non-Patent Literature 1, an amplitude of the luminescence luminance is about 10 times at maximum. The OLED of Non-Patent Literature 1 in which the Ag thin film is formed between the electron-injection layer should have such a structure that a transparent electrode for allowing light to go outside is formed on an organic film (such as hole transportation layer, luminescent layer, etc.). The organic film tends to be damaged in forming the transparent electrode thereon. A technique for manufacturing an element (top emission type element) in which a transparent electrode is formed on an organic film has been studied. However, the top emission type element requires more complicate process than bottom emission type element. Moreover, Ag are easily oxidized. Therefore, it is considered that the use of Ag in the OLED shortens the life thereof. Furthermore, there is a possibility that Ag between the electron-injection layers is ionized to leak into the organic layer, thereby short-circuiting between the cathode and anode.

The present invention was accomplished in view of the aforementioned problem. An object of the present invention is to realize an OLED capable of attaining high luminescence luminance and easy to manufacture.

### Solution to Problem

In order to attain the object, an organic electroluminescence device according to the present invention is an organic electroluminescence device including a luminescent layer between an anode and a cathode, the luminescent layer containing an organic luminescent material, the organic electroluminescence device comprising: a hole transportation layer formed between the anode and the luminescent layer; a metal cluster layer between the anode and the hole transportation layer, the metal cluster layer being a layer in which metal clusters are dispersedly distributed, the metal cluster layer being such that gaps between the metal clusters dispersedly distributed are filled with a hole transportation material.

The metal clusters have an excitation mode by surface plasmon. The surface plasmon of the metal clusters interact with excited electrons in the organic luminescent material of the luminescent layer, thereby reinforcing the luminescence, namely the metal clusters cause SPCE thereof.

With this configuration, the metal clusters dispersedly distributed in the metal cluster layer undergo surface plasmon resonance with the excited electrons in the organic luminescent material of the luminescent layer, thereby reinforcing the luminescence. This can increase luminescence intensity of the organic electroluminescence device.

Moreover, in the luminescent layer, the luminescence due to bonding between electrons and holes takes place mainly in a part near an interface between the luminescent layer and the hole transportation layer. Moreover, the SPCE due to the metal clusters is most effective at a place distanced from the surface of the metal clusters by a certain distance.

This configuration allows the organic electroluminescence device to more effectively reinforce the light mission by the surface plasmon, because the hole transportation layer thus formed separates the surface of the metal clusters and the luminescent layer by the distance suitable for the SPCE. Moreover, the gaps between the metal clusters dispersedly distributed in the metal cluster layer are filled with the hole transportation material. This avoids a decrease in hole transportability and an increase electric resistance in the organic electroluminescence device.

Moreover, the conventional organic electroluminescence device whose luminescence intensity is reinforced by using phosphorescent light is disadvantageous that long relaxing time of the phosphorescent light leads to long excitation period, and consequently high reactivity, thereby likely breaking down the molecules constituting the luminescent layer.

The above configuration can reinforce the luminescence intensity of an organic electroluminescence device without using phosphorescent light. Thus, this configuration can provide the organic electroluminescence device with greater luminescence intensity, a longer life, and lower production cost at the same time.

In order to attain the object, a method according to the present invention for manufacturing an organic electroluminescence device including a luminescent layer between an anode and a cathode, the luminescent layer containing an organic luminescent material is a method comprising: filling a particle dispersion liquid between the anode and a counter member placed to the anode, the particle dispersion liquid in which metal particles are dispersed; providing the metal particles on the anode dispersedly by (i) moving the counter member relatively to the anode in a direction along a surface of the anode, so as to form a meniscus portion of the particle dispersion liquid in a region on the surface of the anode, which region is exposed from the counter member, and by (ii) evaporating a solvent of the particle dispersion liquid; and forming a hole transportation layer so as to fill gaps between the metal particles provided dispersedly and to form the hole transportation layer to cover the metal particles.

With this configuration, the particle dispersion liquid is filled between the anode and the counter member. By changing the positions of the anode and the counter member relatively to each other, an area on the anode is exposed from the counter member and a meniscus portion of the particle dispersion liquid is formed in the exposed area. Here, the meniscus portion of the particle dispersion liquid is a liquid film formed from the particle dispersion liquid due to surface tension of the particle dispersion liquid, the meniscus portion being formed in the area on the anode, which area is exposed from the counter substrate. The solvent of the dispersion liquid is evaporated mainly in the meniscus portion exposed from the counter member. Thus, the particle dispersion liquid is hardly influenced by a temperature change and a humidity change in working environment, thereby making it easier to keep the particle concentration constant in the meniscus portion. Moreover, the area on the anode, in which area the meniscus portion is formed, is defined by the counter member. Thus, it is possible to stabilize where to form the meniscus portion on the anode. Hence, it is possible to provide the metal particles of the particle dispersion liquid on anodes over a wide area (that is, a practical substrate side) uniformly and dispersedly.

Moreover, the method of the present invention is arranged such that the metal particles are provided not by vapor phase epitaxy of metal as in lithography, but by evaporating, in the meniscus portion, the solvent of the liquid in which the metal particles are dispersed. This arrangement provides very high utilization efficiency of the metal raw material. Moreover, the method of the present invention is small in the number of steps and does not require vacuum process. Thus, the method of the present invention just needs small-scale equipment and facility. This lowers the production cost of the organic electroluminescence device. Moreover, the present invention is suitably applicable to organic electroluminescence device of a polymer type, which is manufactured by coating method.

This arrangement allows the organic electroluminescence device to more effectively reinforce the light mission by the surface plasmon, because the hole transportation layer thus formed separates the surface of the metal clusters and the luminescent layer by the distance suitable for the SPCE.

### Advantageous Effects of Invention

An organic electroluminescence device according to the present invention is an organic electroluminescence device including a luminescent layer between an anode and a cathode, the luminescent layer containing an organic luminescent material, the organic electroluminescence device comprising: a hole transportation layer formed between the anode and the luminescent layer; a metal cluster layer between the anode and the hole transportation layer, the metal cluster layer being a layer in which metal clusters are dispersedly distributed, the metal cluster layer being such that gaps between the metal clusters dispersedly distributed are filled with a hole transportation material.

With this configuration, the luminescence intensity of the organic electroluminescence device can be increased by the SPCE. Moreover, this configuration allows the organic electroluminescence device to more effectively reinforce the light mission by the surface plasmon, because the hole transportation layer thus formed separates the surface of the metal clusters and the luminescent layer by the distance suitable for the SPCE. The above configuration can reinforce the luminescence intensity of an organic electroluminescence device without using phosphorescent light. Thus, this configuration can provide the organic electroluminescence device with greater luminescence intensity, a longer life, and lower production cost at the same time.

A method according to the present invention for manufacturing an organic electroluminescence device including a luminescent layer between an anode and a cathode, the luminescent layer containing an organic luminescent material is a method comprising: filling a particle dispersion liquid between the anode and a counter member placed to the anode, the particle dispersion liquid in which metal particles are dispersed; providing the metal particles on the anode dispersedly by (i) moving the counter member relatively to the anode in a direction along a surface of the anode, so as to form a meniscus portion of the particle dispersion liquid in a region on the surface of the anode, which region is exposed from the counter member, and by (ii) evaporating a solvent of the particle dispersion liquid; and forming a hole transportation layer so as to fill gaps between the metal particles provided dispersedly and to form the hole transportation layer to cover the metal particles.

Thus, it is possible to stabilize where to form the meniscus portion on the anode. Hence, it is possible to provided the metal particles of the particle dispersion liquid on anodes over a wide area (that is, a practical substrate side) uniformly and dispersedly. Moreover, the method of the present invention is small in the number of steps and just needs small-scale equipment and facility. This lowers the production cost of the organic electroluminescence device.

### BRIEF DESCRIPTION OF DRAWINGS

FIG. 1

FIG. 1 is a cross sectional view illustrating a structure of an OLED according to one embodiment of the present invention.

FIG. 2

FIG. 2 is a flow chart illustrating a manufacturing method for the OLED according to one embodiment of the present invention.

FIG. 3

FIG. 3 is a schematic view illustrating a general amino silane molecule bonded on an ITO surface of an anode.

FIG. 4

FIG. 4 is a cross sectional view schematically illustrating a cluster layer forming device according to one embodiment of the present invention.

FIG. 5

FIG. 5 is a perspective view schematically illustrating the cluster layer forming device.

FIG. 6

FIG. 6 is a cross sectional view illustrating a structure of an OLED according to another embodiment of the present invention.

FIG. 7

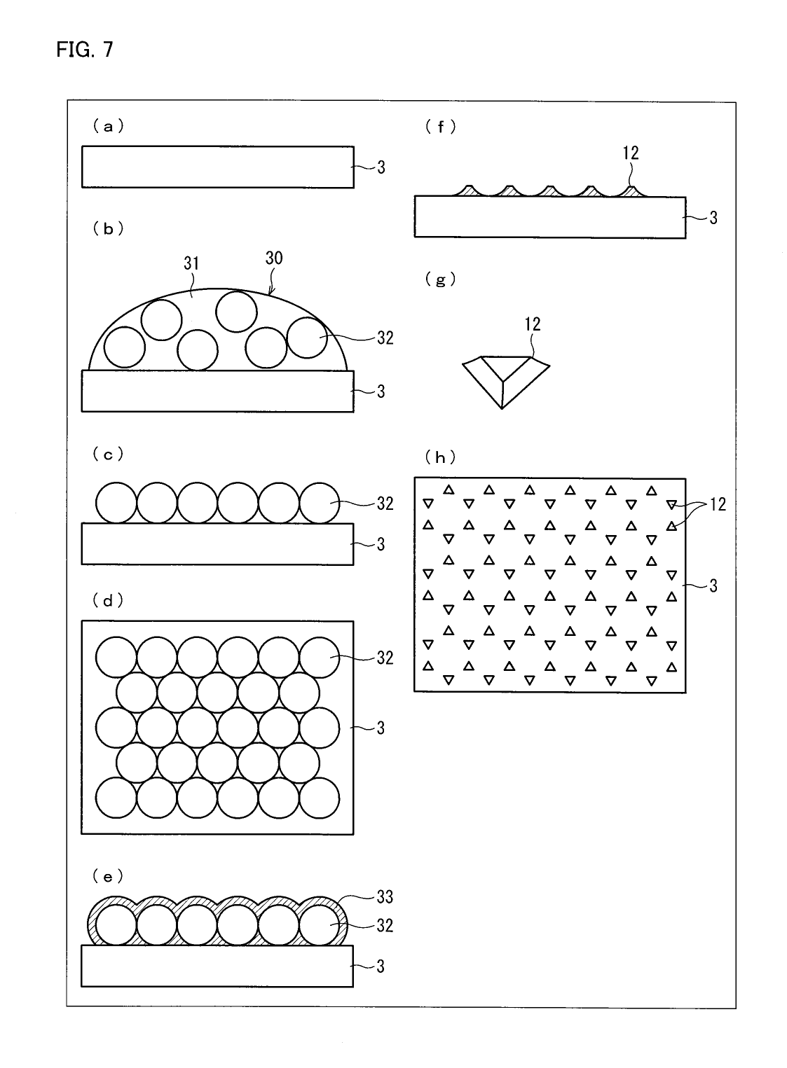

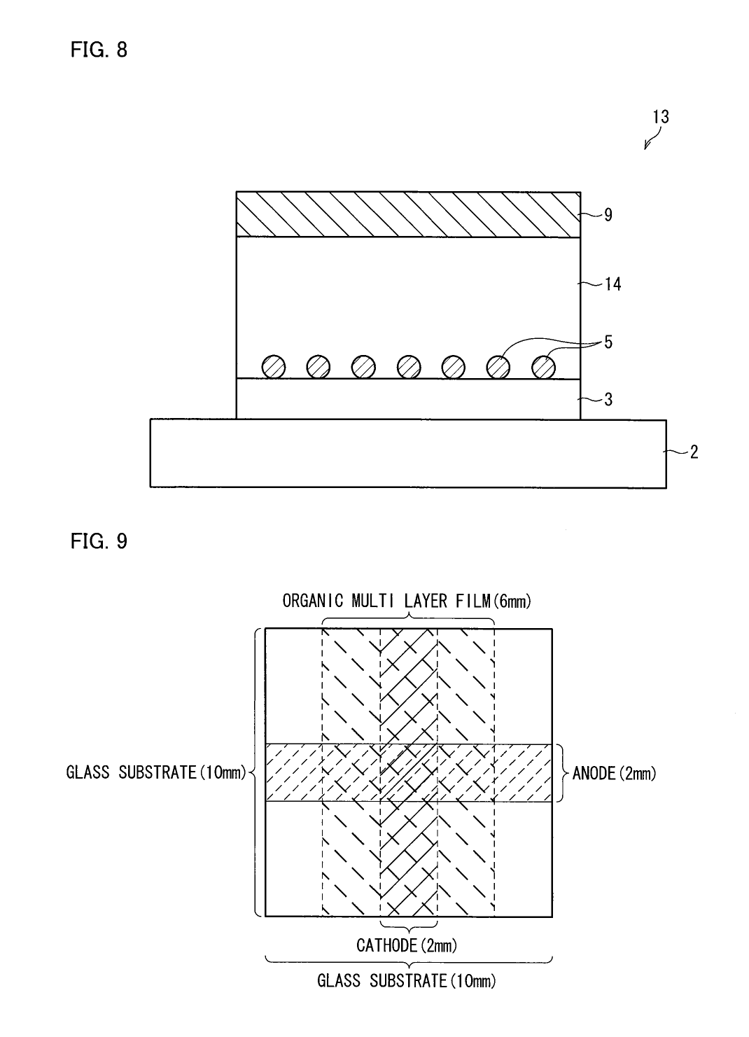

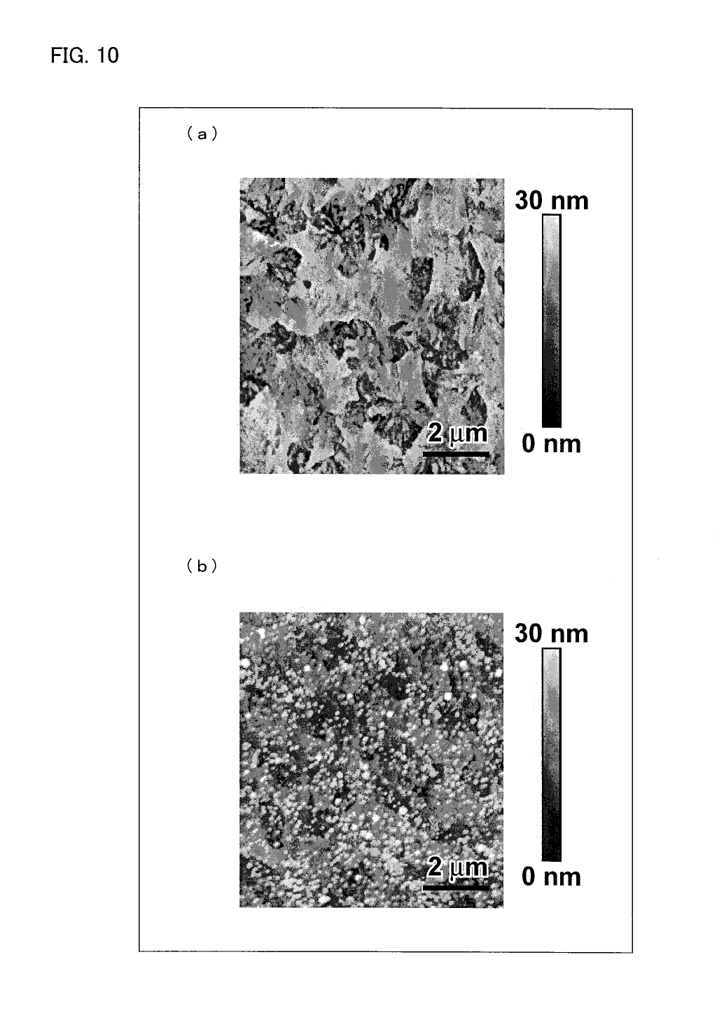

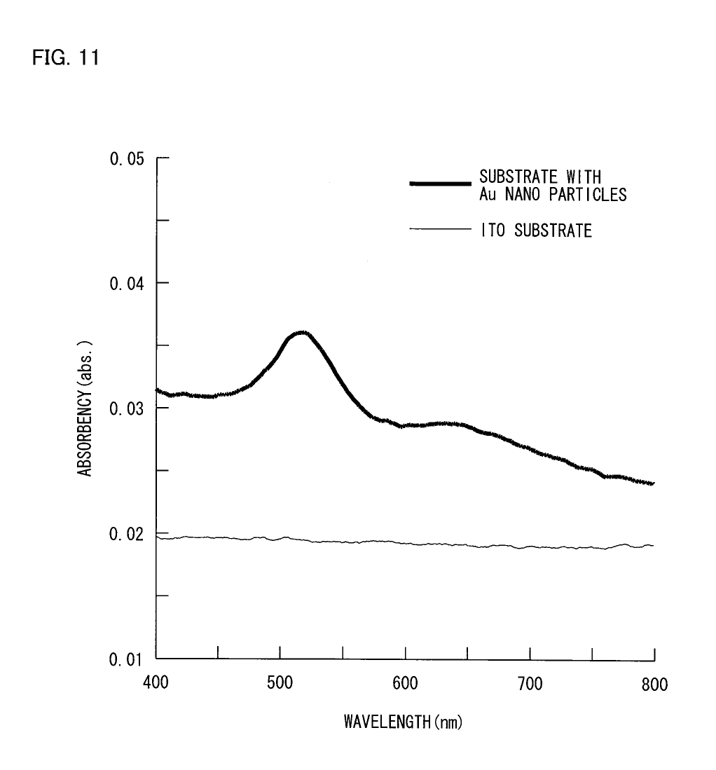

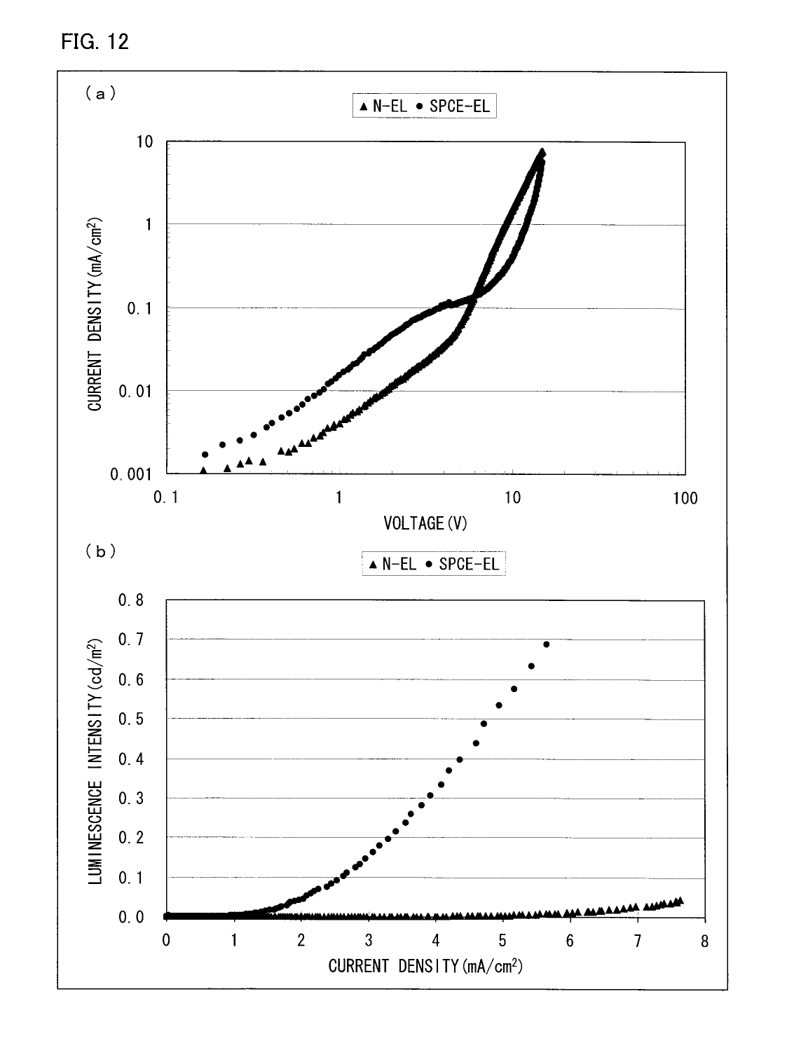

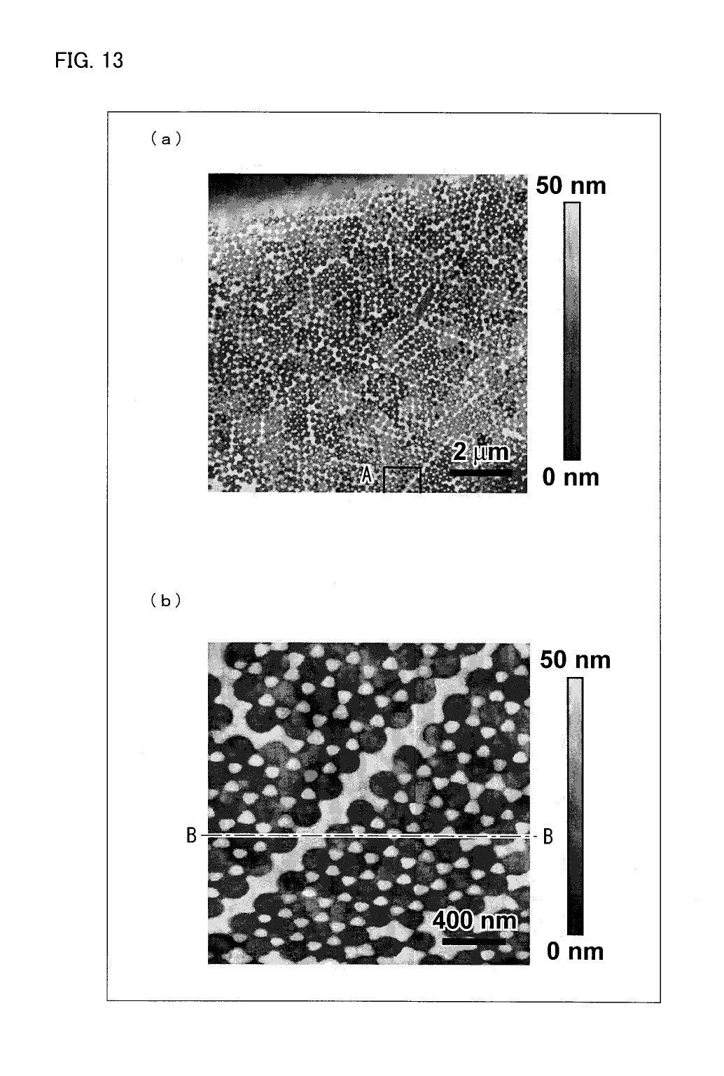

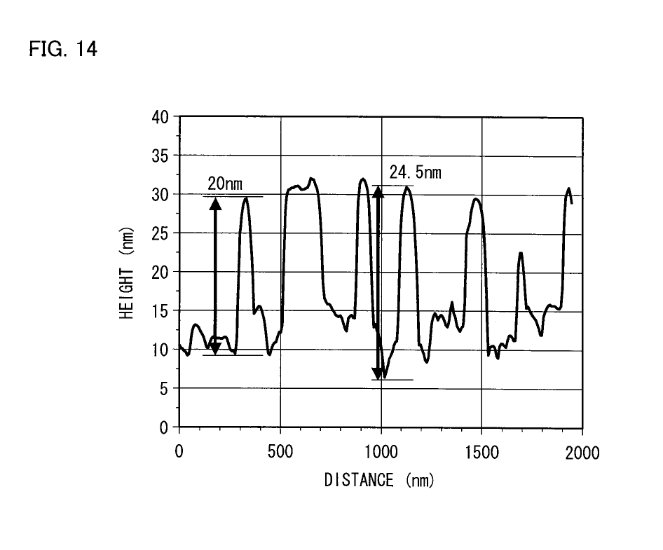

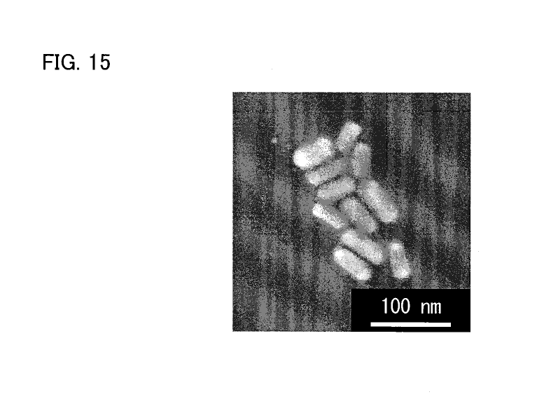

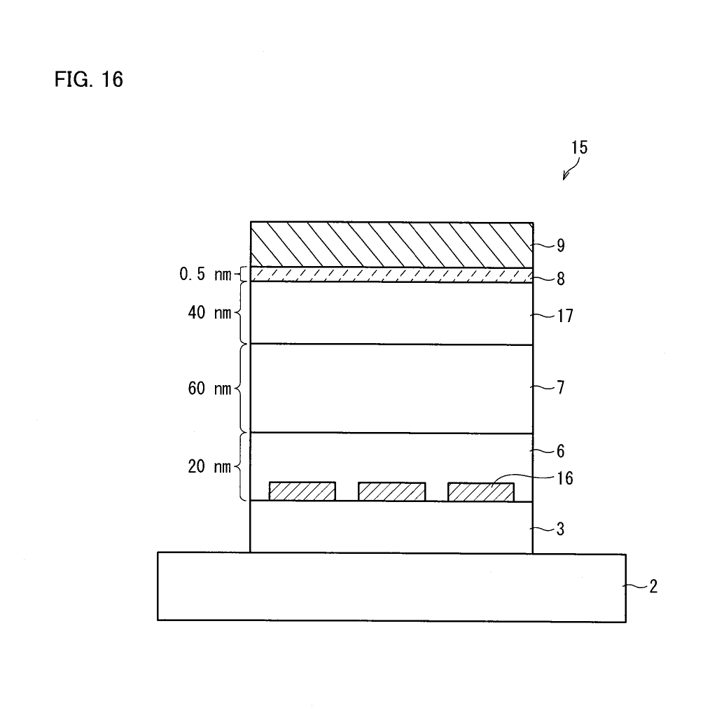

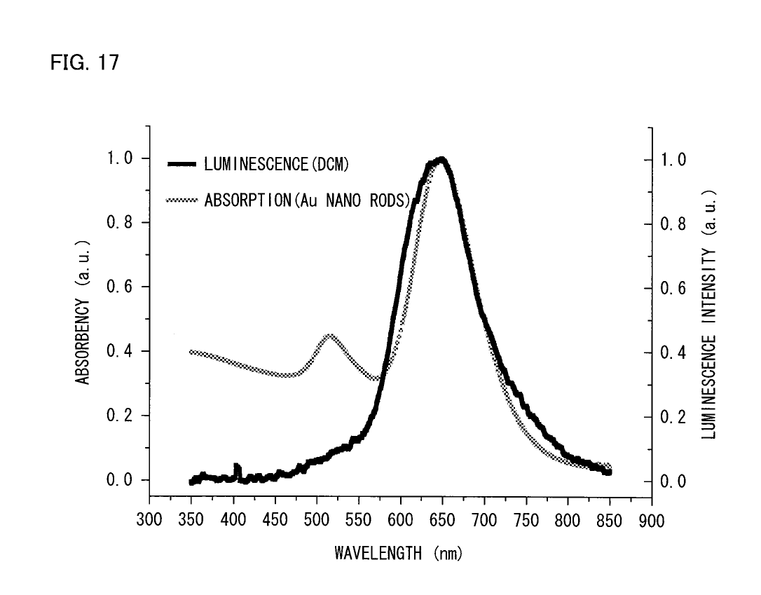

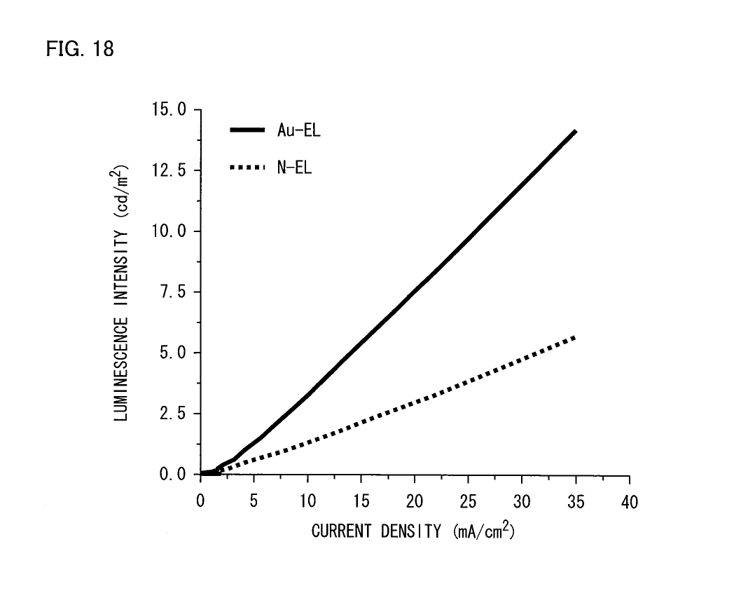

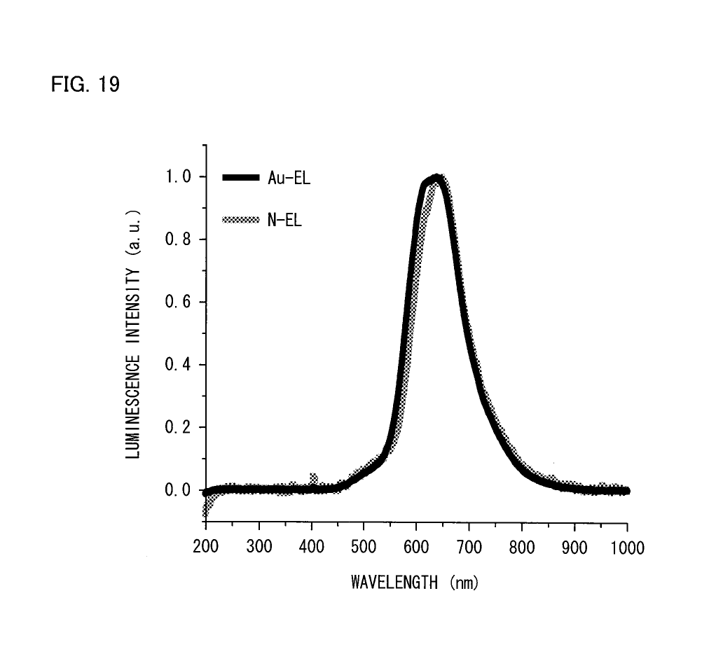

(a) of FIG. 7 is a cross sectional view illustrating an anode made from ITO and formed on a glass substrate. (b) of FIG. 7 is a cross sectional view illustrating a substrate on which a nanosphere mixture liquid is dropped on the anode, in a step of forming a metal nano cluster layer. (c) of FIG. 7 is a cross sectional view illustrating a substrate on which the nanosphere mixture liquid is dried in the step of forming the metal nano cluster layer. (d) of FIG. 7 is a plane view of the substrate illustrated in (c) of FIG. 7. (e) of FIG. 7 is a cross sectional view illustrating a substrate on which metal is deposited in the step of forming the metal nano cluster layer. (f) of FIG. 7 is a cross sectional view illustrating a substrate from which the nanosphere is removed in the step of forming the metal nano cluster layer. (g) of FIG. 7 is a perspective view illustrating a metal nano cluster on the anode. (h) of FIG. 7 is a plane view illustrating a substrate on which the metal nano clusters formed on the anode as illustrated in (g) of FIG. 7.

FIG. 8

FIG. 8 is a cross sectional view illustrating an OLED according to still another embodiment of the present invention.

FIG. 9

FIG. 9 is a plane view illustrating an OLED prepared in one Example of the present invention.

FIG. 10

(a) of FIG. 10 is an atom force microscopic image of an ITO film of a device substrate. (b) of FIG. 10 is an atom force microscopic image of Au nano particles on an AHAPS layer.

FIG. 11

FIG. 11 is a graph plotting absorbency of the device substrate illustrated in (a) of FIG. 10 in which the ITO film was formed on a glass substrate, and absorbency of the device substrate as illustrated in (b) of FIG. 10 in which the Au nano particles were provided on the AHAPS layer.

FIG. 12

(a) of FIG. 12 is a graph illustrating a voltage-current density (V-I) characteristics of an OLED including the Au nano particle layer. (b) of FIG. 12 is a graph illustrating a current density-luminescence intensity (I-L) of the OLED including the Au nano particle layer.

FIG. 13

(a) of FIG. 13 is an atom force microscopic image of a substrate from which nanospheres were removed. (b) of FIG. 13 is a magnified image of Area A shown in (a) of FIG. 13.

FIG. 14

FIG. 14 is a graph illustrating height of a device surface across the Line B in (b) of FIG. 13.

FIG. 15

FIG. 15 is a scanning electron microscopic image of an Au nano rode prepared herein.

FIG. 16

FIG. 16 is a cross sectional view schematically illustrating a structure of an OLED including an Au nano rod layer prepared in another Example of the present invention.

FIG. 17

FIG. 17 is a graph illustrating an absorption spectrum of an Au nano rode dispersion liquid and a luminescence spectrum of light emitting molecules (DCM) of a luminescent layer in the another Example of the present invention.

FIG. 18

FIG. 18 is a graph illustrating a current density-luminescence intensity (I-L) characteristics of an OLED (Au-EL) including the Au nano rode layer of the another Example of the present invention.

FIG. 19

FIG. 19 is a graph illustrating luminescence spectra of the OLED (Au-EL) including the Au nano rode layer of the another Example of the present invention, and a conventional OLED (N-EL) including no Au nano rode layer.

### DESCRIPTION OF EMBODIMENTS

In the following, embodiments according to the present invention are described in more detail, referring to drawings.

### Embodiment 1

### Configuration of OLED

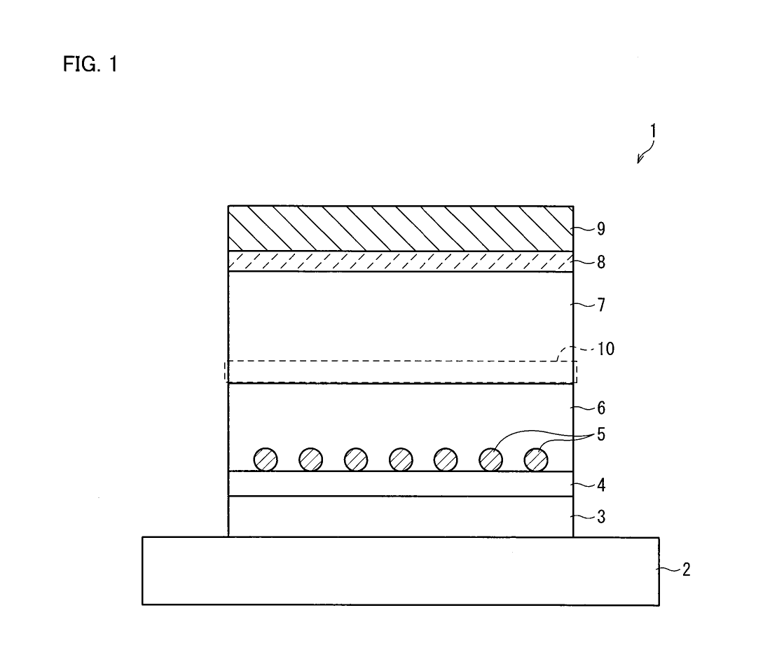

FIG. 1 is a cross sectional view illustrating a configuration of an OLED according to the present embodiment. An OLED 1 includes a glass substrate 2, an anode 3 formed on the glass substrate 2, a binder layer 4 formed on the anode 3, metal nano particles 5 provided dispersedly on the binder layer 4, a hole transportation layer 6 formed on the binder layer 4 and the metal nano particles 5, a luminescent layer 7 formed on the hole transportation layer 6, an electron injection layer 8 formed on the luminescent layer 7, and a cathode 9 formed on the electron injection layer 8. The OLED 1 is an organic electric-field luminescence device in which the luminescent layer 7 is made from an organic luminescent material of a low molecular type.

The glass substrate 2 is a substrate for fabricating the OLED 1 thereon, and is a transparent substrate being transparent to light emitted from the luminescent layer 7.

The anode 3 is a transparent electrode being transparent to the light emitted from the luminescent layer 7, and being electrically conductive. In the present embodiment, the anode 3 is made from ITO (Indium Tin Oxide). The OLED 1 is a light emitting device, which emits light from an anode-3 side.

The binder layer 4 is a layer provided for making it easier for providing the metal nano particles 5 on the anode 3. The binder layer 4 has a function of connecting the anode 3 with the metal nano particles 5. The binder layer 4 is provided on the anode 3 especially in order to provide the metal nano particles 5 dispersedly with uniform density. In the present embodiment, the binder layer 4 is formed from AHAPS(N-6-aminohexyl)-3-amino propyl trimethoxy silane) molecules. It should be noted that the binder layer 4 is not essential to the present invention.

The metal nano particles (metal particles) 5 are nano-size metal clusters formed from metal atoms (typically about 10³ to 10⁷ atoms). On the binder layer 4, the metal nano particles 5 are provided dispersedly with substantially uniform density. It can be considered that the layer in which the metal nano particles 5 are provided dispersedly on the binder layer 4 is a metal nano particle layer (metal cluster layer). In the present embodiment, the metal nano particles 5 are spherical Au (gold) nano particles. Each Au nano particle has a diameter of approximately 12 nm. Moreover, the metal nano particles 5 may be preferably formed from gold, silver, copper, or palladium. Spherical metal nano particles made from any of these metals have a later-described surface plasmon resonance frequency in a visible light range. Moreover, because surface plasmon resonance is largely dependent on a magnitude of an imaginary part of a dielectric constant of metal particles, gold and silver are especially preferable. Beside, noble metals such as platinum, rhodium, iridium, etc., or general metals such as nickel, cobalt, bismuth, etc. can be employed.

The diameter of the metal nano particles used herein is preferably in a range of 5 nm to 100 nm. Moreover, the shape of the metal nano particles is not limited to sphere, but may be any shapes such as rectangular shape, rod-like shape, tetrahedral shape, etc. The wavelength range of the light absorbed by the later-described surface plasmon of the metal nano particles is largely dependent on the shape of the metal nano particles. Therefore, by adjusting the rectangular or rod-like shaped metal nano particles in terms of length, the wavelength of the light to be absorbed by the metal nano particles can be adjusted to a wavelength at which the desired surface plasmon resonance occurs. Moreover, the number of the metal atoms contained in the metal nano particles is not limited to the above example.

The hole transportation layer 6 is a layer containing a material excellent in hole transportability. In the present embodiment, the hole transportation layer 6 is made from copper phthalocyanine (CuPc). Gaps between the dispersedly distributed metal nano particles 5 are filled with the same hole transportable material from which the hole transportation layer 6 is made.

The luminescent layer 7 is made from an organic luminescent material, which emits light as a result of bonding between holes and electrons. In the present embodiment, the luminescent layer 7 is made from tris (8-hydrox quinolino)aluminum complex (Alq₃). Alq₃ is also excellent in electron transportability. Therefore, the luminescent layer 7 also functions as an electron transportation layer.

The electron injection layer (cathode buffer layer) 8 is a layer for connecting the luminescent layer 7 made from an organic material, and the cathode 9 made from an inorganic material, so as to make it easier to inject electrons into the luminescent layer 7. In the present embodiment, the electron injection layer 8 is made from lithium fluoride (LiF).

The cathode 9 is an electrode made from aluminum in the present embodiment.

Moreover, the OLED may be configured to include a hole barrier layer between the hole transportation layer 6 and the luminescent layer 7. The hole barrier layer may be made from, for example, LiF, MgF₂, or the like.

The OLED 1 has a configuration in which the metal nano particles 5 are dispersed in plane between the anode 3 and the luminescent layer 7. In general, metal nano particles interact with light of a particular wavelength range by surface plasmon. By this, the metal nano particles absorb the light of the particular range, thereby exciting surface plasmon.

It is known that, in general, a fluorescent molecule provided in the vicinity of metal lose its energy without causing luminescence because the energy of exited electrons is transferred to the metal. A ratio (probability) of the transfer of the exited energy in the fluorescent molecule to the metal without causing luminescence is smaller inversely proportionally to third power of a distance between the metal and the fluorescent molecule in case it can be supposed that the metal has a flat surface having a semi-infinitely thick thickness. The ratio (probability) is smaller inversely proportionally to 4th power of the distance between the metal and the fluorescent molecule in case it can be supposed that the metal has a flat surface having an infinitely thin thickness. The ratio (probability) is smaller inversely proportionally to the 6th power of the distance in case it can be supposed that the metal is in the form of fine particles.

Meanwhile, it is known that, under conditions in which the surface plasmon resonance takes place on the surface of the metal, fluorescent luminescence of a fluorescent molecule (light emitting molecule) is reinforced by the surface plasmon resonance. The luminescence reinforced by the surface plasmon is called Surface Plasmon Coupled Emission (SPCE). The conditions under which the surface plasmon resonance takes place are: excited energy of the fluorescent molecule is within the energy of the light to be absorbed by the surface plasmon, that is, the wavelength of the light of the fluorescent luminescence of the fluorescent molecule is within the wavelength of the light absorbed by the surface plasmon. If the metal and the fluorescent molecule are distanced too far, the resonance between the surface plasmon and the fluorescent molecule cannot occur, whereby the reinforcement to the fluorescent luminescence is reduced. If the metal and the fluorescent molecule are too closed to each other, electric field caused by the fluorescent molecule causes dielectric loss within the metal fine particles, whereby the energy of excitation is lost without causing luminescence, resulting in nonradiative deactivation. Nonradiative deactivation rate becomes greater in proportion with 6th power of the distance. Therefore, as the metal and the fluorescent molecule are closer to each other, the probability of the nonradiative energy loss is dramatically increased.

The quenching due to energy transfer to the metal competes with the fluorescent luminescence reinforcement caused by the surface plasmon resonance. The fluorescent luminescence becomes optimal when the metal and the fluorescent molecule are distanced by a certain distance. In the case of the combination of the Au nano particles and the luminescent material Alq₃, the luminescence is most intensively reinforced when the distance of the Au nano particles and the luminescent material Alq₃ is in a range of 10 nm to 30 nm.

In the present embodiment, the luminescence due to the bonding between the electrons and holes can occur in the whole luminescent layer 7. The bonding of electrons and holes takes place at most in an area 10 of the luminescent layer 7, which area 10 is near the hole transportation layer 6. Therefore, the luminescence of the OLED 1 mainly takes place in the area (light emitting area) 10 of the luminescent layer 7. The metal nano particles 5 are about 12 nm in diameter and the hole transportation layer 6 is about 20 nm in thickness in the present embodiment. The hole transportation layer 6 is formed, for example by vapor deposition, on the surface which the metal nano particles 5 are provided on and is rough. Therefore, the hole transportation layer 6 has an upper surface (interface between the hole transportation layer 6 and the luminescent layer 7), which is actually rough, reflecting where each metal nano particle 5 is. Moreover, the luminescent layer 7 has a thickness of about 100 nm. Thus, the distance between the spherical metal nano particles 5 and the light emitting area 10 of the luminescent layer 7 is approximately in a range of 8 nm to 20 nm. Thus, the interaction (coupling) between the excited electrons in the luminescent layer 7 and the surface plasmon of the metal nano particles 5 take place intensively, thereby causing the luminescence reinforcement due to the surface plasmon so as to cause the OLED 1 to emit light more intensively.

The OLED 1 is configured such that the metal nano particles 5 are provided above the anode 3 with the binder layer 4 provided therebetween. Therefore, the distance between the metal nano particles and the light emitting area 10 of the luminescent layer 7 can be adjusted by changing the thickness of the hole transportation layer 6. Therefore, by analyzing a plurality of samples prepared with different thicknesses of the hole transportation layer 6, it is possible to easily determine how thick the hole transportation layer 6 should be in order to attain optimal luminescence reinforcement when the metals nano particles 5, hole transportation 6, the luminescent layer 7, or the like is formed from a certain material.

In general, not all the excited electrons injected into the luminescent layer contribute to the luminescence. The electrons in the singlet excited state contribute to the fluorescent luminescence. Some of the electrons in the singlet excited state undertakes the luminescence process to emit light, thereby losing their energy, and the other convert their excited energy to thermal energy without passing through the luminescence process. Luminescence (radiation deactivation) of the organic EL molecule relaxes the excitation state in the order of μs to ns. On the other hand, the conversion to the heat energy in the organic EL molecule (non-radiation deactivation) relaxes the excitation state in the order of ns to 10 ps. That is, the relaxing time caused by the conversion to the heat energy ends in a shorter time than the relaxing time caused by the luminescence process. Thus, a large portion of the electrons in the singlet excited state are deactivated without contributing the luminescence.

However, the OLED 1 in the present embodiment has a relaxing process due to the luminescence reinforced by the surface plasmon. Relaxing time for relaxing the excitation state by the surface plasmon is approximately in the order of ps, which is equivalent to the relaxing time caused by the conversion to the heat energy. Thus, the luminescence reinforced by the surface plasmon speeds up the luminescence of the electrons, thereby bringing the electrons to their ground state. This decreases the number of the excited electrons consumed to generate the heat energy in vain. As a result, the luminescence of the OLED 1 can be reinforced.

Moreover, because the fluorescent molecule excited by the electrons injected from the cathode 9 emits light earlier thereby being brought to the ground state earlier. This makes it possible to inject more electrons into the OLED 1. This improves the OLED 1 in luminescence intensity by flowing a greater amount of current therethrough.

In general, the transparent electrode is ITO in OLEDs. However, ITO has a large work function and is poor in electron injectability. Thus, ITO is not suitable for cathode and is used for anode. In order to use ITO as the cathode, a complicate process is necessary and it is not efficient. Thus, in general the OLEDs are configured such that light is emitted from the anode side. Therefore, it would be generally a problem that, if metal etc. is provided on or above the transparent electrode serving as anodes, the metal blocks light emitted from the luminescent layer. However, the OLED 1 in the present embodiment is configured such that a mono layer of the metal nano particles 5 dispersedly scattered over the anode 3 is formed and therefore most of the light emitted from the luminescent layer 7 is propagated toward the anode 3 and the glass substrate 2. Thus, the luminescence intensity of the OLED 1 can be greatly reinforced without losing the effect of the SPCE. Specific transmittance of the metal nano particle layer will be explained later in Examples.

The OLED 1 of the present embodiment is an organic light emitting device capable of reinforcing the luminescence without using doping of the phosphorescent luminescent material, etc. as in the conventional art. Because of this, the problem that the dopant becomes impurity to shorten the life of the light emitting device can be solved, thereby prolonging the life of the OLED. Meanwhile, the SPCE of the metal nano particles and the luminescence of the phosphorescent luminescent material using the phosphorescent light differ in their mechanisms. Accordingly, it is possible to reinforce the luminescence in combination of the two mechanisms, by doping the luminescent layer of the OLED 1 of the present embodiment with the phosphorescent luminescent material.

<Manufacturing Process for OLED>

In the present embodiment, an advective accumulation method is used to provide the metal nano particles 5 on the binder layer 4 on the anode 3.

The advective accumulation method is to immerse, in a solvent to which the substrate has affinity, a flat substrate (such as glass) in a dispersion liquid (such as aqueous solution) in which particles are dispersed for a long time, so as to form a mono particle layer film on the substrate. In this method, autonomous accumulability of the particles on an interface between the substrate and the particle dispersion liquid is utilized to attain high-density accumulation of the particles. So far, the film formation of the particle film by the advective accumulation method is carried out by using a dip coater, mainly (for example, see Non-Patent Literature 2). However, the conventional advective accumulation method has such a problem in that it is difficult to form a particle film on a practical-size substrate with high accuracy. More specifically, in this method, the particle film thus formed would have uneven density in the same plane due to disturbance such as temperature or humidity in working environment, thereby making it difficult to form uniform particle film on the practical-size substrate.

In view of this, the present embodiment is arranged such that uniquely-modified version of advective accumulation method is used to provide the metal nano particle on the substrate dispersedly and uniformly. That is, by using a particle dispersion liquid containing the metal nano particles, the metal nano particles are provided on the binder layer 4 formed on the anode 3 dispersedly and uniformly.

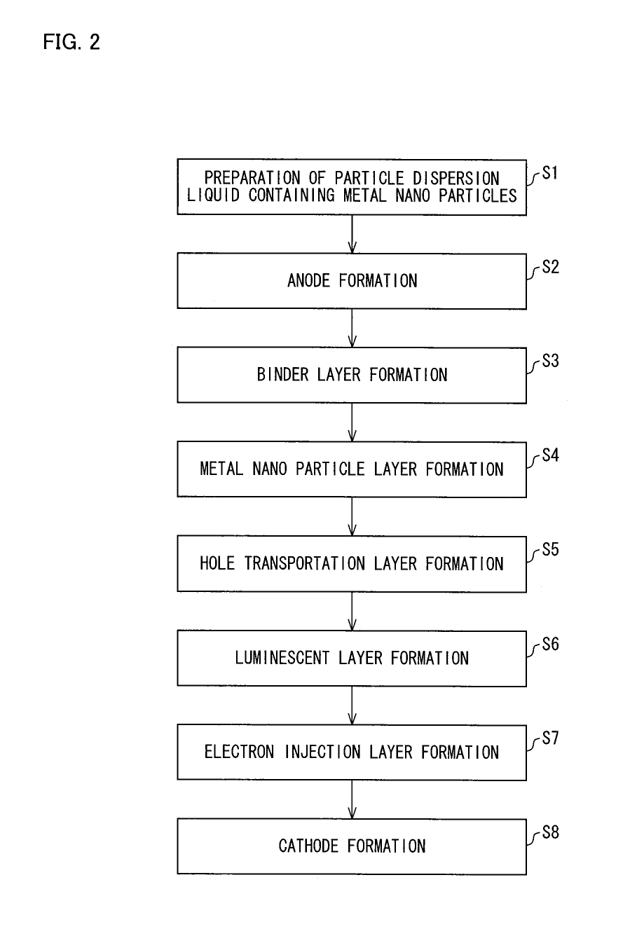

FIG. 2 is a flow chart illustrating such a manufacturing method of the OLED of the present embodiment. The manufacturing method of the OLED of the present embodiment mainly includes (S1) preparing a particle dispersion liquid containing metal nano particles, (S2) forming an anode, (S3) forming a binder layer, (S4) forming a metal nano particle layer, (S5) forming a hole transportation layer, (S6) forming a luminescent layer, (S7) forming an electron injection layer, (S8) forming a cathode. In the following the steps are explained in more detail.

<Step of Preparing a Particle Dispersion Liquid Containing Metal Nano Particles>

In this step, a particle dispersion liquid containing, as dispersed particles, the metal nano particles 5 for forming the metal nano particle layer is prepared. The metal nano particles are provided on the binder layer 4 dispersedly, thereby forming the metal nano particle layer. Thus, it is preferable that the metal nano particles 5 contained in the particle dispersion liquid have a size and a shape satisfying conditions required by the OLED 1 finally obtained. The conditions are determined in consideration of the wavelength of the light emitted from the luminescent layer 7, the transparency of the metal nano particle layer, the thickness of the hole transportation layer 6, etc. For example, spherical metal nano particles of 5 nm to 100 nm in diameter can be employed. In the present embodiment, the metal nano particles 5 are prepared in the solution. For example, this allows to easily form small metal nano particles of 50 nm or less, which are difficult to prepare by lithography in which metal nano particles are vapor-grown by using a CVD method (chemical vapor deposition method).

In order to adjust concentration of the dispersed particles locally in the particle dispersion liquid by electric field in the later step of forming the metal nano particle layer, it is preferable that the metal nano particles 5 are electrically charged particles in the particle dispersion liquid.

In order to attain a colloid of the metal nano particles 5, it is necessary to positively or negatively electrify the surfaces of the metal nano particles 5 in the particle dispersion liquid. Moreover, it is preferable that zeta potential of the metal nano particles is high positively or negatively, in order that high concentration of the metal nano particles 5 may not hinder disintegrated dispersion of the metal nano particles 5 in the later step of forming the metal nano particle layer and uniformly providing the metal nano particles 5 on the binder layer 4 in the later step of forming the metal nano particle layer, even if the metal nano particles 5 are high in concentration. For this reason, it is preferable that the surface of the metal nano particles in the particle dispersion liquid is modified such that the zeta potential of the metal nano particles is −35 mV or less or +35 mV or more. For example, in case of the Au nano particles, for example, trisodium citrate and/or tannin acid is added to the particle dispersion liquid in order to adjust the zeta potential of the Au nano particles.

Moreover, the adjustment of the zeta potential of the metal nano particles may be carried out by introducing, to the surface of the metal nano particles, (a) a silane coupling agent having an amino group, carboxyl group, a hydroxyl group, or sulfo group, or the like, (b) organic molecules having a thiol group at their terminals, or (c) an anionic or cationic surfactant (or its hydrochloride or bromide). Moreover, the adjustment of the zeta potential of the metal nano particles may be carried out by changing pH in the particle dispersion liquid.

The metal nano particles may be made from a general metal such as nickel, cobalt, bismuth, apart from a noble metal such as gold, platinum, silver, copper, palladium, rhodium, and iridium. Moreover, plural types of metal nano particles may be used in combination. For example, in case where a metal nano particle layer in which Pt nano particles and Au nano particles are dispersed is formed by using a particle dispersion liquid in which Pt nano particles and the Au nano particles are mixed together, the Pt nano particles and the Au nano particles excite surface plasmon different in resonance wavelength. This makes it possible to cause resonance with light of plural types of wavelengths. That is, in case plural types of luminescent material (fluorescent or phosphorescent) is used in the luminescent layer, it is possible to cause SPCE in the luminescence materials, thereby improving the luminescence efficiency. Moreover, it is possible to use a mixture of metal nano particles having different size or shapes.

Moreover, the shape of the metal nano particles is not limited to sphere, and may be any shape such as, for example, a triangular pyramid, a quadrangular pyramid, cube, rectangular parallelepiped, rod-like shape, or the like.

The solvent in the particle dispersion liquid is not particularly limited, provided that the solvent allows electrification of the metal nano particles in the solution. For example, the solvent may be (a) ultrapure water, (b) an aqueous solution in which ion species such as sodium, calcium, or the like is dissolved in ultrapure water, (c) ionic liquid, (d) a polymer aqueous solution, (e) or the like.

The concentration of the particles in the particle dispersion liquid may be changed, depending on a transportation speed of the substrate (i.e., forming speed of the metal nano particle layer) in the later step of forming the metal nano particle layer, and on a coating ratio of the metal nano particle layer to be formed.

<Step of Forming an Anode>

On the glass substrate 2, an ITO film is formed, so as to form the anode 3, which is a transparent electrode. The ITO film may be carried out by a conventional method. Moreover, a commercially available ITO glass substrate (on which a substrate on which an ITO film is formed on a glass substrate) may be employed. Moreover, the anode may be formed from another material being transparent to light emitted from the luminescent layer 7, and being electrically conductive.

<Step of Forming a Binder Layer>

In order to facilitate the formation of the metal nano particle layer on the anode 3, the binder layer 4 is formed on the anode 3. The binder layer 4 has a function of connecting the anode 3 with the metal nano particles 5. Especially, it is preferable that the metal nano particles 5 are formed on the anode 3 in order to dispersedly provide the metal nano particles 5 with uniform density.

In case where the metal nano particles 5 are Au nano particles, the binder layer 4 may be, for example, (a) a polymer thin film layer having an amino group or amine-type self-assembled monomolecular layer made from modified polyethylene imine, polyvinyl pyrolidone, polyvinyl pyrrolidine, or the like, (b) a layer of hydrocarbon polymer (such as polystylene) containing a trace of oxygen, nitrogen, and steam, and being activated with atmospheric plasma whose main component is a noble gas such as He or Ar.

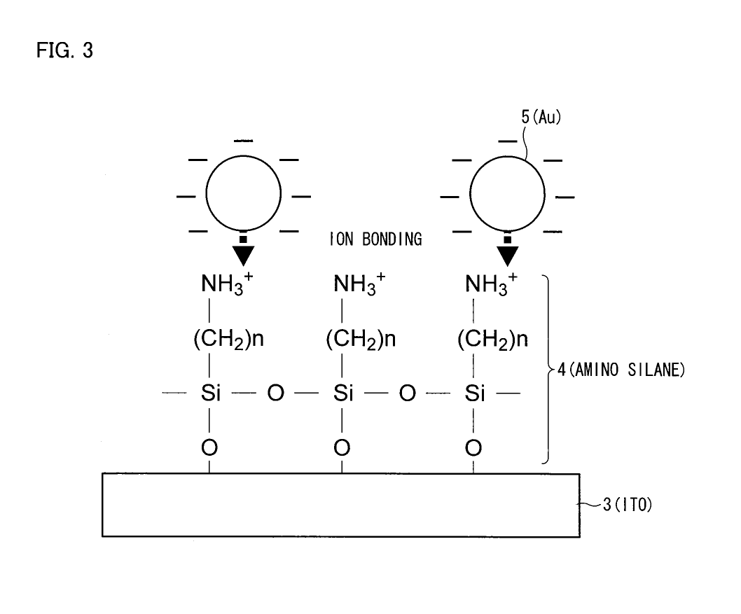

The zeta potential of the Au nano particles is negative in the particle displayer liquid. Thus, the Au nano particles can be dispersedly provided uniformly with high density by forming the binder layer from AHAPS(N-6-aminohyexyl)-3-amino propyl trimethoxy silane molecules, which is a silane coupling agent (amino silane) having an amino group at its terminal and is an amine-type self-assembling monomolecular layer, among these examples of layers. It is deduced that the Au nano particles can be dispersedly provided uniformly with high density because the amino group at the terminal of the AHAPS molecule bonded to the ITO of the anode 3 is positively electrified in the particle dispersion liquid and attract the negatively-electrified Au nano particles. FIG. 3 is a schematic diagram illustrating an amino silane molecule bonded with the ITO surface of the anode 3. By silane coupling, the amino silane molecule bonds with the ITO, which is an oxide. By this, an amino silane molecule film is formed on the ITO surface. Moreover, especially, in case the binder layer 4 is to be formed from AHAPS, it is possible to form a monomolecular layer on a wide range of the anode 3, thereby forming a binder layer 4 being flat over a wide range. The use of AHAPS makes it possible to form the binder layer 4 as a monomolecular layer, whereby substantially constant zeta potential can be attained with high reproducibility. This allows to provide the metal nano particles 5 highly reproducibly with desired distribution density in the later step of forming the metal nano particle layer. Moreover, the flat surface of the binder layer 4 is advantageous for providing the metal nano particles 5 uniformly in the later step of forming the metal nano particle layer. By forming the binder layer 4 from a silane coupling agent having an amino group at its terminal, it is possible to provide the metal nano particles 5 dispersedly and uniformly with high density. Note that some of the amino groups are ionized to be ammonium ions (−NH₃+) in the aqueous solution.

Moreover, the binder layer may be formed from (a) amino group-terminal silane coupling agent such as APS (3-amino propyl silane), (b) halogen salt of the silane coupling agent (that is, silane coupling agent having an ammonium salt at its terminal), or (c) an amine-type polymer such as P4vP (poly 4 vinyl pyridine) or polyment (registered trademark; Nippon Shokubai Co. Ltd.). Examples of the silane coupling agent having an amino group at its terminal encompass materials of “SIA0587.0” to “SIA0630.0” shown in the site of Non-Patent Literature 3. However, the binder layer formed from APS is inferior to the one formed from AHAPS in terms of the reproducibility of the zeta potential of the binder layer, because the binder layer formed from APS is formed as a multi layer. Moreover, the binder layer formed from P4VP or polyment can be formed as a super thin film of approximately 20 nm by spin coating or the like. However, in case where a step of removing the binder layer is carried out later, it is more difficult to remove the binder layer of P4VP or polyment without disturbing the uniform distribution of the metal nano particles, compared with the binder layer of AHAPS. Thus, the binder layer formed from AHAPS is more preferable.

In case of the metal nano particles whose zeta potential is positive in the particle dispersion liquid, it is possible to provide the metal nano particles dispersedly and uniformly with high density by forming the binder layer from a silane coupling agent having a negatively-charged hydroxyl group or carboxyl group at its terminal. Examples of the silane coupling agent having a terminal hydroxyl group encompass hydroxyl ethyl methyl amino propyl triethoxy silane etc. Examples of the silane coupling agent having a terminal carboxyl group encompass 2-carboxy methyl thio ethyl trimethoxy silane and the like. Moreover, in case of the metal nano particles whose zeta potential is neutral in the particle dispersion liquid, it is possible to similarly provide the metal nano particles dispersedly and uniformly with high density by forming the binder layer from a silane coupling agent having a thiol group at its terminal. Examples of the silane coupling agent having a terminal thiol group encompass 3-mercapto propyl triethoxy silane and the like.

In the later step of forming the metal nano particle layer, the metal nano particles are provided preferentially in the area on the binder layer, to the area off the binder layer. Thus, in case where the metal nano particles are the Au nano particles and the binder layer is formed from AHAPS, it is possible to form the Au nano particle layer only in the area on the binder layer by controlling where to form the binder layer. Molecules of AHAPS are degradable by ultraviolet irradiation. Thus, by selectively irradiating ultraviolet rays to the binder layer of AHAPS on the anode 3 by using masking or the like, it is possible to leave the binder layer of AHAPS only in desired areas. By this, it is possible to form the Au nano particle layer only in desired areas. Moreover, this allows to use expensive noble metal material in a highly efficient manner.

The present invention is not limited to this, and may be configured such that the metal nano particle layer (and the binder layer 4 and cathode 3) is partially removed by lithography after the binder layer of AHAPS is formed all over the anode 3 and the metal nano particle layer is formed on the binder layer.

<Step of Forming a Metal Nano Particle Layer>

In the step of forming a metal nano particle layers in the present embodiment, a first substrate (in which the anode 3 is formed on the glass substrate 2 and the binder layer 4 is formed on the anode 3), and a second substrate (counter member) are positioned face to face. Then, the particle dispersion liquid of the metal nano particles is filled between the first and second substrates. After that, while positionally shifting the first substrate along its surface facing the second substrate (in a direction parallel to the surface), the solvent in the particle dispersion liquid is evaporated in a meniscus portion, of the particle dispersion liquid, on the first substrate exposed from the second substrate. By this, the metal nano particles 5 are dispersedly provided on the first substrate (that is, on the binder layer 4), thereby forming the metal nano particle layer.

Further, the step of forming the metal nano particle layer may include measuring concentration of the metal nano particles in the meniscus portion; and adjusting the concentration of the metal nano particles in the meniscus portion based on the concentration thus measured in the step of measuring.

(Particle Layer Forming Device)

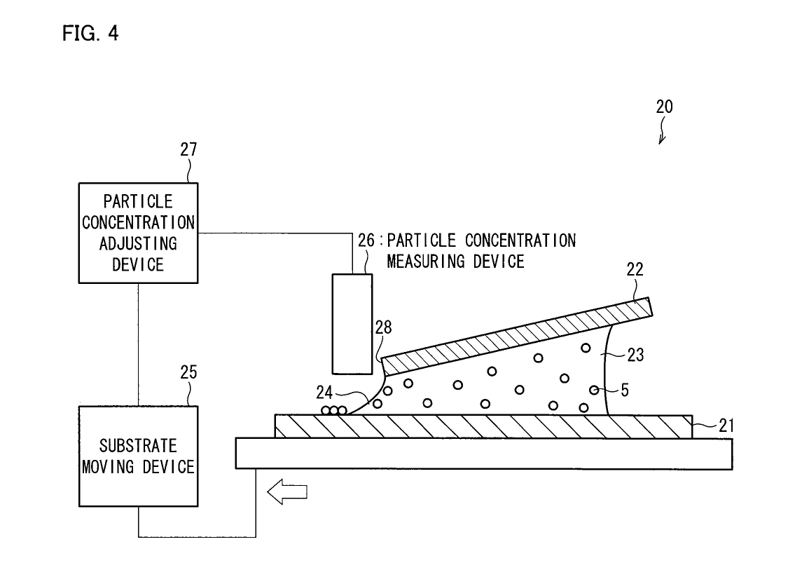

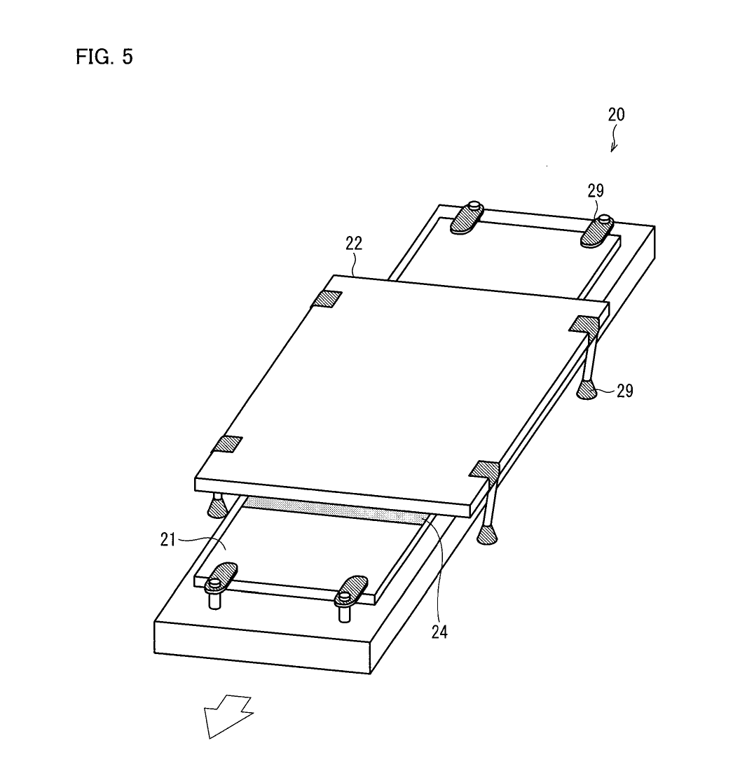

FIG. 4 is a cross sectional view schematically illustrating a particle layer forming device in the present embodiment. FIG. 5 is a perspective view schematically illustrating the particle layer forming device.

As illustrated in FIGS. 4 and 5, a particle layer forming device 20 according to the present embodiment is a device for forming the metal nano particle layer on a first substrate 21 by evaporating the solvent in a particle dispersion liquid 23 containing metal nano particles 5 and filling a gap between the first substrate 21 and a second substrate 22 facing each other, wherein the particle layer forming device 20 performs the evaporation by evaporating the solvent in a meniscus portion 24 formed in a direction of the movement of the first substrate 21 while moving the first substrate 21 relatively to the second substrate 22 along the surface of the anode on the first substrate 21. The second substrate 22 holds the particle dispersion liquid 23 between the second substrate 22 and the first substrate 21. While the first substrate 21 is moved relatively to the second substrate 22, the meniscus portion 24 is formed in an area where the particle dispersion liquid 23 is exposed on the first substrate 21 from the second substrate 22. Even though they are not illustrated here, the anode and binder layer are formed on that surface of the first substrate 21 which faces the second substrate 22.

The particle layer forming device 20 includes a substrate positioning member 29 for positioning the first substrate 21 and the second substrate 22 in a way to face each other, a substrate moving device 25 for changing the relative position of the first substrate 21 with respect to that of the second substrate 22 along an in-plane direction of the first substrate 21, a particle concentration measuring device (physical amount measuring device) 26 for measuring the particle concentration of the metal nano particles 5 in the meniscus portion 24, and a particle concentration adjusting device 27 for adjusting the particle concentration in the meniscus portion 24 on the basis of the particle concentration (physical amount) measured by the particle concentration measuring device 26.

A distance between the first substrate 21 and the second substrate 22 in the meniscus portion 24 may be selected in consideration of the diameter etc. of the metal nano particles 5. For example, the distance between the first substrate 21 and the second substrate 22 in the meniscus portion 24 may be 20 μm or less.

In the present embodiment, the first substrate 21 and the second substrate 22 are positioned such that the second substrate 22 is inclined to the first substrate 21, so that the distance between the first substrate 21 and the second substrate 22 becomes shorter at the forward-side edge in the direction in which the position of the first substrate 21 is changed (indicated by the arrow in FIGS. 4 and 5) than at the backward-side edge.

The second substrate may be parallel with or inclined to the first substrate. However, it is preferable that the second substrate is inclined to the first substrate, so that the distance between the first substrate 21 and the second substrate 22 becomes shorter at the forward-side edge in the direction in which the position of the first substrate 21 is changed than at the backward-side edge. By causing the distance between the first substrate and the second substrate to be shorter at the side where the solvent is evaporated to form the metal nano particle layer than the opposite side, it is possible to hold a greater amount of the particle dispersion liquid between the first and second substrate, and further to form the meniscus portion on the first substrate in the direction of the positional change of the first substrate in such a way that the meniscus portion is formed with positional stability (length stability of the meniscus portion) with respect to an edge of the second substrate. This allows the solvent to be evaporated at a constant rate, thereby making it possible to form the metal nano particle layer with a uniform density.

In case where the second substrate is provided such that the second substrate is inclined to the first substrate, an angle between the surface of the first substrate and the surface of the second substrate may be, for example, not less than 0.05° but not more than 0.5°.

The second substrate is not limited to a particular material, and may be a glass substrate, a metal substrate, a metal oxide substrate, a metal nitride substrate, a semiconductor substrate, a polymer substrate, an organic crystal substrate, a flat mineral substrate such as mica, or the like.

Moreover, the second substrate may not be flat, but may have a structure having an edge protruded toward the first substrate, which edge is in the direction of the positional change of the first substrate. That is, instead of the second substrate, a counter member may be used. The counter member is positioned to face the anode and the binder layer on the first substrate so as to locally cover the anode and the binder layer on the first substrate and hold the particle dispersion liquid between the binder layer of the first substrate and counter member. The counter member is positioned with a minute gap between the binder layer of the first substrate and an edge of the counter member covering the first substrate (which edge is located at a position at which the binder layer of the first substrate is exposed from the counter member). The counter member may include a member for filling or replenishing the particle dispersion liquid between the counter member and the first substrate. With such a structure, it is possible to stabilize the position of the meniscus portion on the binder layer of the first substrate with respect to the edge of the counter member, thereby making it possible to attain the metal nano particle layer with uniform density. Moreover, the metal nano particles may be provided directly on the anode without forming the binder layer.

(Substrate Positioning Member)

The substrate positioning member 29 is not particularly limited, provided that the substrate positioning member 29 can position the first substrate 21 and the second substrate 22 face to face. For example, as illustrated in FIG. 5, the substrate positioning member 29 may be configured such that the second substrate 22 is fixed with a fixing tool such as a clump, so that the first substrate 21 is fixed to a platform having a mounting surface and being provided with a fixing tool such as a clump. In such a case, the relative position of the first substrate 21 with respect to the second substrate 22 can be changed along the in-plane direction of the first substrate 21 by moving, in the direction of the arrow in FIGS. 4 and 5 by the substrate moving device 25, the platform on which the first substrate 21 is fixed.

(Substrate Moving Device)

The substrate moving device 25 is not particularly limited, provided that the position of the first substrate 21 can be changed relative to the position of the second substrate 22 by the substrate moving device 25. The substrate moving device 25 in the present embodiment is configured to move the first substrate 21 by using a stepping motor. Alternatively, the substrate moving device 25 may be configured to move the second substrate 22 by using a stepping motor or the like, while the first substrate 21 is fixed, or the substrate moving device 25 may be configured to move both the first substrate 21 and the second substrate 22.

(Particle Concentration Measuring Device)

The particle concentration measuring device 26 is not particularly limited, provided that the particle concentration in the meniscus portion 24 can be measured by the particle concentration measuring device 26. For example, the particle concentration measuring device 26 may be configured to measure the particle concentration by using an electrostatic capacitance meter, or by utilizing light scattering or light reflection.

For example, in case where the particle concentration is measured by measuring electrostatic capacitance, the particle concentration measuring device may include an electrostatic capacitance meter and a particle concentration calculating device for calculating the particle concentration based on the electrostatic capacitance measured by using the electrostatic capacitance meter. The electrostatic capacitance in the meniscus portion of the particle dispersion liquid reflects the particle concentration in the meniscus portion. Thus, by measuring the electrostatic capacitance in the area including the meniscus of the particle dispersion liquid, the particle concentration in the meniscus can be measured. How to measure the particle concentration by using an electrostatic capacitance meter is described below.

(Particle Concentration Measuring Method)

A method for measuring the particle concentration in the present embodiment measures the particle concentration in the meniscus formed on the first substrate by changing the position of the first substrate to the particle dispersion liquid with which the first substrate is in contact.

In the method for measuring the particle concentration, the electrostatic capacitance in the area including the meniscus portion is measured and the particle concentration is determined based on the electrostatic capacitance thus measured.

For example in case where the substrate on which the meniscus portion is formed is electrically conductive, the measurement of the electrostatic capacitance of the particle dispersion liquid can be carried out by measuring, in a non-contact manner, the electrostatic capacitance formed between the probe and the substrate via the meniscus portion. More specifically, the substrate is grounded and the probe of the electrostatic capacitance meter is positioned to face the area in which the meniscus of the particle dispersion liquid is formed on the substrate. Then, the electrostatic capacitance between the probe and the substrate is measured.

If the substrate is not electrically conductive, a probe to form the electrostatic capacitance within the probe may be used. For example, a probe (product name: 2810) uniquely developed by KLA Tencor Corp. or the like probe can be used to measure the electrostatic capacitance between the probe and the substrate by utilizing spread of an electric field effectively. In this case, by setting a distance between the probe and the substrate to 1 mm or less, it is possible to attain a sensitivity equivalent to that of the case where the substrate is electrically conductive.

As long as the area including the particle dispersion liquid contained in the meniscus is measured, the measurement of the electrostatic capacitance can be performed for any part. For example, the measurement of the electrostatic capacitance may measure only electrostatic capacitance in the meniscus portion (which consists of the particle dispersion liquid and an air layer between the particle dispersion liquid and the probe), or measure electrostatic capacitance in an area including the meniscus portion, the particle dispersion liquid, the second substrate, and the air layer between the second substrate and the probe.

The position of the probe is preferably to cover the meniscus portion substantially wholly. Here, it is preferable that the position of the probe does not overlap with the metal nano particle layer, which has been already formed. As long as these conditions are met, the probe may partially overlap with the second substrate in the present embodiment in which the particle layer is formed by using the pair of substrates. Because the influence from the second substrate on the electrostatic capacitance is unchanged, the change in the electrostatic capacitance thus measured represents a change in the particle concentration. Moreover, in case the probe of KLA Tencor Corp. is used, the change in the particle concentration can be measured excellently regardless of the position of the probe, as long as the distance of a tip of the probe and the substrate is 1.5 mm or less.

To perform high-resolution measurement of the change in the electrostatic capacitance due to the change in the particle concentration, it is preferable to position the probe near the substrate. More specifically, in case the particle layer is formed from a material having relatively small dielectric constant, the distance between the probe and the substrate is preferably not less than 200 μm but no more than 1.0 mm. Moreover, in case where the particle layer is formed from a material having relatively large dielectric constant (such as inorganic semiconductor, metal, or the like), the probe can detect the change even if the probe is distanced from the substrate. Thus, in this case, the distance between the probe and the substrate is preferably not less than 200 μm but no more than 3.0 mm. By positioning the probe in the distance in the range, it is possible to prevent the particle layer from being formed right under the probe, thereby making it possible to perform excellent electrostatic capacitance measurement.

A probe with a smaller diameter makes is possible to perform measurement to measure a smaller area locally. In case of the present embodiment in which the pair of substrates are used to form the particle layer, such a probe with a smaller diameter faces a greater risk of forming unexpected electrostatic capacitance between the probe and the edge of the second substrate. Moreover, some electrostatic capacitance meter would be more restricted as to the distance between the probe and the substrate, when the prove has a smaller diameter. For this reason, it is preferable to use a probe whose diameter is in the order of 10 mm.

In case where the particles have greater dielectric constant than the solvent of the dispersion liquid, the electrostatic capacitance measured is high if the particle concentration in the meniscus portion is high, and the electrostatic capacitance measured is low if the particle concentration in the meniscus portion is low, in the method for measuring the particle concentration. This is, the particle concentration and the electrostatic capacitance have a linear relationship. Thus, the particle concentration can be determined from the measurement of the electrostatic capacitance, based on a function between the particle concentration and the electrostatic capacitance, which function has been worked out by calculation or like.

Moreover, in case where particles having lower dielectric constant than the solvent of the dispersion liquid, the particle concentration and the electrostatic capacitance is in inverse proportion. Thus, the particle concentration can be similarly determined from the measurement of the electrostatic capacitance, based on a function between the particle concentration and the electrostatic capacitance, which function has been worked out by calculation or like.

Moreover, the method for measuring the particle concentration is preferably arranged such that the particle concentration is determined in consideration of an extent of warping of the substrate, in addition to the electrostatic capacitance. This makes it possible to measure and adjust the particle concentration with higher accuracy.

The measurement of the warping of the substrate is not necessary if the first substrate on which the metal nano particle layer is to be formed has no warping. However, a thin board-like article is warped in general. The warping changes the distance between the probe and the substrate in measuring the electrostatic capacitance. This would cause error in the measurement of the particle concentration. Therefore, by measuring the warping of the substrate and measuring the particle concentration in consideration of the extent of the warping, it is possible to measure and adjust the particle concentration with higher accuracy.

For example, the measurement of the warping may be carried out by measuring the electrostatic capacitance between another probe of an electrostatic capacitance meter and the substrate, wherein the another probe is provided to face that surface of the first substrate, which is opposite to the surface on which the meniscus is formed, and calculating the warping of the first substrate from the electrostatic capacitance thus measured.

The particle concentration measuring device 26 in the present embodiment includes an electrostatic capacitance meter, whose probe is positioned above the second substrate 22 so that the probe faces the area in which the meniscus of the particle dispersion liquid occurs on the first substrate 21. Moreover, the first substrate 21 is grounded. The electrostatic capacitance meter is configured to measure the electrostatic capacitance of the area consisting of the meniscus portion 24, the particle dispersion liquid, the second substrate 22, and the area consisting of the air layer between the second substrate 22 and the probe.

(Particle Concentration Adjusting Device)

The particle concentration adjusting device 27 in the present embodiment is configured to adjust the particle concentration in the meniscus portion 24 by adjusting a substrate moving speed of moving the first substrate 21 by the substrate moving device 25. The meniscus portion 24 is supplied with the particle dispersion liquid from the area covered with the second substrate 22, when the solvent is evaporated. In general, the evaporation of the solvent in the meniscus portion 24 causes the particle concentration to be higher than the area covered with the second substrate 22. Thus, when the substrate moving speed is reduced, a greater amount of the solvent is evaporated in a constant area in the meniscus portion 24 on the first substrate 21, thereby increasing the number of the metal nano particles concentrated. This increases the particle concentration of the meniscus portion 24. On the other hand, when the substrate moving speed is increased, the particle concentration in the meniscus portion 24 is reduced. Therefore, by adjusting the substrate moving speed, the particle concentration in the meniscus portion 24 can be adjusted.

Again in case where a substrate moving device moves the second substrate or moves both of the first substrate and the second substrate, the particle concentration can be adjusted by changing the relative substrate moving speed.

Moreover, the particle concentration adjusting device may be configured to adjust the particle concentration in the meniscus portion by applying an electric field between the first substrate and the second substrate. In case the particle concentration adjusting device is configured to adjust the particle concentration in the meniscus portion by applying an electric field between the first substrate and the second substrate, it is preferable that the second substrate has an electrically conductive surface. In this case, examples of the second substrate encompass an ITO glass, an FTO (fluorine-tin-oxide) substrate, a ZnO₂ (zinc oxide) substrate, a semiconductor substrate, a metal substrate, an electrically conductive polymer substrate, and the like.

As illustrated in FIG. 4, a line connecting (a) the edge 28, being in contact with the particle dispersion liquid 23 in the meniscus portion 24, of the second substrate 22, and (b) the first substrate 21 in contact with an edge of the meniscus portion 24 of the particle dispersion liquid 23 is not perpendicular to the surface of the first substrate 21 but inclines from the edge 28 of the second substrate 22 outwardly toward the area of the first substrate 21, which area is uncovered with the second substrate 22. Therefore, when a voltage is applied between the first substrate 21 and the second substrate 22, electrical flux lines from the second substrate 22 to the first substrate 21 are directed to the meniscus portion 24 extended outwardly from the second substrate 22. Thus, by applying an electric field from the first substrate 21 to the second substrate 22, it is possible to move the particles into the meniscus portion 24.

The particle concentration adjusting device is not limited to these configurations and may be configured to add to the particle dispersion liquid a more or less concentrated particle dispersion liquid, for example. As long as the particle concentration adjusting device 28 has a configuration capable of adjusting the particle concentration in the meniscus portion 24, it is possible to attain an effect similar to that of the present embodiment. Examples of such a configuration encompass a configuration of adding a more or less concentrated particle dispersion liquid by using a pump, a syringe, a tube head, or the like.

To adjust the change of the particle concentration by adjusting the substrate moving speed is most stable and further is easy to keep the particle concentration constantly. In the present embodiment, the particle concentration adjusting device 27 is configured to adjust the particle concentration by adjusting the substrate moving speed. The particle concentration adjusting device 27 adjusts the substrate moving speed, so that the particle concentration measured by the particle concentration measuring device 26 is kept within a certain range. For example, the particle concentration measuring device 26 measures the particle concentration every several ten msec. The particle concentration adjusting device 27 adjusts the substrate moving speed based on particle concentration measured by the particle concentration measuring device 26, if the particle concentration thus measured is out of a certain range. By controlling in this way, the particle concentration is brought back to the range within several hundred msec. By keeping the particle concentration in the meniscus portion 24 constant, it is possible to attain a metal nano particle layer with uniform distribution density of the metal nano particles.

The electrostatic capacitance actually measured by the electrostatic capacitance meter includes the electrostatic capacitance of the second substrate 22 and the like. Thus, in order to calculate the particle concentration of the meniscus portion 24, the electrostatic capacitance of the second substrate 22 and the like is measured in advance in order to subtract influence of the electrostatic capacitance of the second substrate 22 and the like from the result of the measurement. Moreover, a value (or a range) of the particle concentration for attaining a metal nano particle layer with a desired distribution density can be found out by performing an experiment to measure a distribution density of metal nano particles in a metal nano particle layer formed with a certain particle concentration and a substrate moving speed, and calculating the following relational expression using the distribution density of the metal nano particles in metal nano particle layer.

c=k×φ/(v(1−φ))

where c is a distribution density, k is a constant, φ is the particle concentration in the dispersion liquid (volumetric concentration), v is the moving speed (μm/s) of the first substrate. By finding k from the relational expression, it is possible to obtain a value (or range) of the particle concentration for obtaining the metal nano particle layer with a desired distribution density.

Note that it is not necessary to calculate out the actual particle concentration, in case where the particle concentration is regulated to be constant (kept within a predetermined range). In this case, it is only required to adjust the substrate moving speed in such a way that the value of the electrostatic capacitance (physical amount) measured by the electrostatic capacitance is kept within a predetermined range. The predetermined range of the electrostatic capacitance can be changed depending on the desired distribution density of the metal nano particles in the metal nano particle layer, the kind of the metal nano particles, the solvent and additive in the particle dispersion liquid, the temperature and humidity of the environment, the distance between the first substrate and the second substrate at their edges in the forward direction of the moving direction of the first substrate, the size and kind of the second substrate, and etc. For this reason, the value (or range) of the electrostatic capacitance to obtain the metal nano particle layer with the desired density may be obtained experimentally, and the particle concentration adjusting device 27 may be configured to adjust the substrate moving speed according to a difference between the electrostatic capacitance measured by the particle concentration measuring device 26 and the predetermined range of the electrostatic capacitance, so that the electrostatic capacitance measured by the particle concentration measuring device 26 will be within the predetermined range of the electrostatic capacitance.

<Step of Forming a Hole Transportation Layer>

In the step of forming a hole transportation layer, the hole transportation layer 6 is formed, by vapor deposition, on the substrate on which the metal nano particles 5 are dispersed on the binder layer 4. The hole transportation layer 6 may be formed by vacuum vapor deposition of a material of the hole transportation layer (copper phthalocyanine in the present embodiment) as in a conventional art. In forming the hole transportation layer 6, the thickness of the hole transportation layer 6 is adjusted so that the distance from the metal nano particles 5 to the luminescent layer 7 becomes suitable for the SPCE.

In order to manufacture an OLED of a low molecular type, some of hole transportation materials allow spin-coating for forming the hole transportation.

<Step of Forming a Luminescent Layer>

In the step of forming a luminescent layer, the luminescent layer 7 is formed on the hole transportation layer 6 by vapor deposition. The formation of the luminescent layer 7 may be performed by vacuum vapor deposition of a material of the luminescent layer 7 (Alq₃ in the present embodiment) as in a conventional art).

<Step of Forming an Electron Injection Layer>

In the step of forming an electron injection layer, the electron injection layer 8 is formed on the luminescent layer 7 by vapor deposition. The electron injection layer 8 may be formed by vacuum vapor deposition of a material of the electron injection layer 8 (lithium fluoride in the present embodiment) as in a conventional art.

<Step of Forming a Cathode>

In the step of forming a cathode, the cathode 9 is formed on the electron injection layer 8 by vapor deposition. The cathode 9 may be formed by vacuum vapor deposition of a material of the cathode (aluminum in the present embodiment) as in a conventional art).

In this way, an OLED 1 as illustrated in FIG. 1 is obtained. After that, sealing is performed in order to protect the OLED 1 from atmosphere, humidity, etc.

In general, an OLED is manufactured by forming these components in the order of from the ITO glass substrate side, that is, by forming, on the glass substrate, the transparent anode made from ITO, the hole transportation layer, the luminescent layer, the electron injection layer, and the cathode in this order as if they are laminated on each other. In general, the preparation of the ITO glass substrate and the following film forming steps (steps for forming hole transportation layer, the luminescent layer, electron injection layer, and the cathode, respectively) are performed by different manufacturing devices. Thus, it is possible to manufacture an OLED 1 of the present embodiment by using conventional facility by adding the step of forming the metal nano particle layer on the anode 3. Moreover, in case of a configuration in which metal nano clusters are provided on the cathode, it is necessary to provide the metal nano cluster on the organic films (hole transportation layer, luminescent layer, and the like) after the organic films are formed. For example, the organic film serving as a platform for the metal nano clusters in the step of forming the metal nano clusters by vacuum process is easily damaged during the step. In the present embodiment, only the anode made from ITO, and the binder layer, have been formed on the glass substrate at the stage of forming the metal nano particle layer. Thus, the organic films such as hole transportation layer, luminescent layer, and the like will not be damaged by the formation of the metal nano particle layer in the present embodiment.

According to the method for manufacturing an OLED in the present embodiment, the step of forming the metal nano particle layer can form the metal nano particle layer without using a lithography device. Thus, according to the advective accumulation method according to the present embodiment, it is possible to form the metal nano particle layer with less steps compared with the use of lithography requiring complicate steps. The particle layer forming device 20 for use in the step of forming the metal nano particle layer is smaller in size and lower in cost than a lithography device. Moreover, the small size of the particle layer forming device 20 eliminates the need of a conventional large clean room. This reduces equipment cost. Moreover, in case where the solvent of the particle dispersion liquid is water, the metal nano particle layer is formed by evaporating mainly water. This is environmentally friendly.

In the case where the metal nano cluster is formed by using the lithography, formable shapes of the metal nano cluster are restricted. For example, in the present embodiment in which the metal nano particles are formed in the solution and provided by the advective accumulation method, the spherical metal nano particles can be formed and provided. Moreover, it is possible to prepare the metal nano particles with a triangular pyramid shape or the other shape. The wavelength range of the light absorbed by the metal nano particles is largely changed when the shape of the metal nano particles is changed. Thus, it is possible to easily obtain metal nano particles having an absorption peak in a desired wavelength range.

<Other Examples of Steps>

In the present embodiment, the hole transportation layer 6 is formed on the binder layer 4 and the metal nano particles 5 after the metal nano particles 5 are provided on the binder layer 4. However, it may be arranged such that the binder layer 4 is removed after the metal nano particles 5 are provided on the binder layer 4. The binder layer 4 is provided in order to cause the metal nano particles 5 to be dispersed dispersedly and uniformly. Thus, it is possible to arrange such that the binder layer 4 is removed after the metal nano particles 5 are provided. Moreover, the binder layer 4 made from AHAPS in the present embodiment does not affect the luminescence efficiency etc. of the OLED 1 substantially. On the other hand, if AHAPS is degraded over time, the degradation produces a material, which is impurity for the OLED 1. This would adversely affect the life of OLED 1. Therefore, it is preferable to have a step of removing the binder layer after the step of forming the metal nano particle layer.

For example, the binder layer made from organic molecules can be removed by being degraded by using atmospheric He plasma. In case the binder layer is made from AHAPS, the removing process using the atmospheric He plasma causes the metal nano particles 5 dispersedly scattered on the binder layer 4 on the anode 3 to be moved on the anode 3 as dispersedly scattered. That is, the step of removing the binder layer makes it possible to obtain a substrate on which the metal nano particles 5 are dispersedly and uniformly distributed on the anode 3. By performing the step of forming the hole transportation layer and the like similarly thereafter, it is possible to obtain an OLED having no binder layer.

The removal of the binder layer may be carried out by another chemical process such as ozone process, or a physical process, depending on the material of the binder layer.

A step of forming a hole blocking layer may be provided, after the step of forming the hole transportation layer. In the step of forming the hole blocking layer, a hole blocking layer is formed by vapor deposition of a material (e.g., LiF, MgF₂, or the like) of the hole blocking layer by vacuum vapor deposition.

Moreover, a step of forming an electron transportation layer may be provided after the step of forming the luminescent layer. In the step of forming the electron transportation layer, an electron transportation layer is formed by vapor deposition of a material of the electron transportation layer on the luminescent layer by vacuum vapor deposition. In the present embodiment, Alq₃ constituting the luminescent layer functions as both the luminescent layer and the electron transportation layer.

### Embodiment 2

The present embodiment describes an OLED having a metal nano cluster structure in which metal nano clusters, instead of the metal naon particles, are dispersedly provided on an anode. For the sake of easy explanation, the like members and configurations having the same functions as the member and configuration described in Embodiment 1 are labeled in the same manner as those described in Embodiment 1 and their explanation is not repeated here.

<Configuration of OLED>

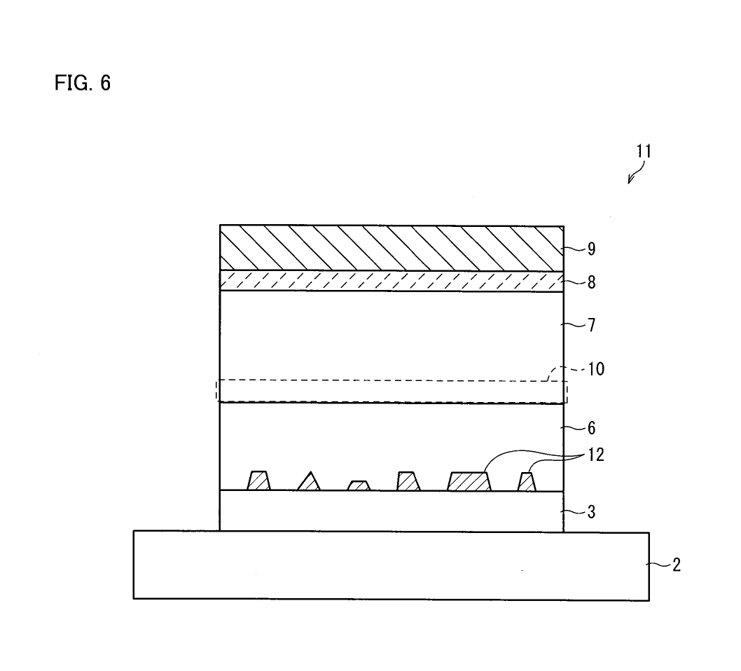

FIG. 6 is a cross sectional view illustrating a configuration of an OLED according to the present embodiment. An OLED 11 includes a glass substrate 1, an anode formed on the glass substrate 2, metal nano clusters 12 distributed on the anode 3 dispersedly, a hole transportation layer 6 formed on the anode 3 and the metal nano cluster 12, a luminescent layer 7 formed on the hole transportation layer 6, an electron injection layer 8 formed on the luminescent layer 7, and a cathode 9 formed on the electron-injection layer 8. The OLED 11 is an organic electroluminescence device using an organic luminescent material of a low molecule type. The OLED 11 is identical with the OLED in Embodiment 1 as to the configurations of the glass substrate 2, the anode 3, the luminescent layer 7, the electron injection layer 8, and the cathode 9. Therefore, their explanation is not repeated here.

The metal nano clusters 12 are metal nano cluster of nano size, made from metal atoms. The metal nano clusters 12 are distributed dispersedly on the anode 3. The metal nano clusters 12 are not uniform in shape and have various cross sectional shapes such as trapezoids, triangles, rectangles, etc. A layer in which the metal nano clusters 12 are dispersedly distributed and which is provided on the anode 3 can be referred to as a metal nano cluster layer (metal cluster layer). In the present embodiment, the metal nano clusters 12 are Au nano clusters. Each Au nano cluster is approximately in a range of 20 nm to 25 nm in height, and approximately in a range of 100 nm to 200 nm in width of its bottom surface. Moreover, like the metal nano particles, the metal nano clusters 12 may be formed from a noble metal such as gold, platinum, silver, copper, palladium, rhodium, or iridium. Beside, the metal nano clusters 12 may be formed from a general metal such as nickel, cobalt, bismuth.

The hole transportation layer 6 is made from copper phthalocyanine (CuPc) as in Embodiment 1, and has a thickness of about 20 nm. The hole transportation layer 6 is formed, by vapor deposition, on a rough surface on which the Au nano clusters 12 are provided. Thus, the hole transportation layer 6 actually has an upper surface (interface between the hole transportation layer 6 and the luminescent layer 7) that reflects the roughness caused by the Au nano clusters 12.

The OLED 11 has a configuration in which the metal nano clusters 12 are dispersed in plane on the anode 3. Due to surface plasmon, the metal nano clusters intensively interact with light of a particular wavelength range, like the metal nano particles. By this the metal nano clusters absorb light of the particular wavelength range, hereby exciting the surface plasmon. This feature allows the metal nano clusters to reinforce luminescence by surface plasmon. The particular wavelength range of the light absorbed by the surface plasmon of the metal nano clusters is changed depending on the shapes of the metal nano clusters.

In the OLED 11, the metal nano clusters 12 interacts with the luminescent material of the luminescent layer 7, thereby causing luminescence reinforcement due to the surface plasmon, like the metal nano particles. Thus, the OLED 11 of the present embodiment is greater in luminance of the luminescence than an OLED having no metal nano clusters 12.

The OLED 11 of the present embodiment is an organic light emitting device capable of reinforcing luminescence without conventionally-performed doping of the phosphorescent luminescent material, as in Embodiment 1. This prolongs the life of OLED by solving the problem that the dopant is turned into impurity shortening the life of the light emitting device.

The OLED may be of top emission type, by configuring the cathode to be made from a member transparent to light of the wavelength, which light is emitted from the luminescent layer.

<Steps of Manufacturing Process of OLED>

In the present embodiment, the metal nano clusters 12 are formed on the anode 3 by using a vapor deposition method. The method for manufacturing an OLED according to the present embodiment mainly includes a step of forming an anode, a step of forming a metal nano cluster layer, a step of forming a hole transportation layer, a step of forming a luminescent layer, a step of forming an electron injection layer, and a step of forming a cathode. Here, the step of forming an anode, the step of forming a hole transportation layer, the step of forming a luminescent layer, the step of forming an electron injection layer, and the step of forming a cathode can be performed in the same manner as in Embodiment 1, and their detailed explanation is not repeated here. In the following, the step of forming metal nano cluster layer is described in detail.

<Step of Forming Metal Nano Cluster Layer>

In the following, the step of forming metal nano cluster layer is described, referring to (a) to (h) of FIG. 7. In Non-Patent Literature 4, a method for forming metal nano clusters by vapor deposition is disclosed. The step of forming metal nano cluster layer mainly includes a step of forming nano spheres, a step of performing metal vapor deposition, and a step of removing nano spheres.

(Step of Forming Nano Sphere)

(a) of FIG. 7 is a cross sectional view illustrating an anode 3 formed on a glass substrate and made from ITO. Note that the glass substrate is not illustrated herein. The substrate provided with the anode 3 is washed with acetone • isopropyl alcohol (IPA).

On the anode 3 on the substrate thus washed, a nano sphere mixture liquid is dropped. The nano sphere mixture liquid is a mixture of nano sphere (spherical shape) made from polystyrene with a diameter of about 200 nm, and ethanol as a solvent. The size of the nano sphere is not limited to this size, and may be changed according to a desired size of the metal nano clusters to be formed. (b) of FIG. 7 is a cross sectional view illustrating the substrate on which a nano sphere mixture liquid 30 is dropped on the anode 3 in the step of forming the metal nano cluster layer. The nano sphere mixture liquid 30 contains a solvent 31 and nano spheres 32.

Next, the substrate is naturally dried to evaporate off the solvent 31. (c) of FIG. 7 a cross sectional view illustrating the substrate on which the nano sphere mixture liquid is dried in the step of forming metal nano cluster layer. The nano spheres 32 are arranged on the metal anode 3. Density of the nano spheres 32 is varied depending on concentration and a dropped amount of the nano sphere mixture liquid. In the case illustrated in (c) of FIG. 7, the nano spheres 32 are arranged with high density, thereby forming a monomolecular layer film. (b) of FIG. 7 is a plane view illustrating the substrate illustrated in (c) of FIG. 7. On the anode 3, the nano spheres 32 are arranged with a substantially maximum density in a plane view. Note that two layers of the nano spheres 32 may be formed to obtain a two-layered film.

(Step of Performing Metal Vapor Deposition)

Next, metal from which the metal nano clusters will be formed is vapor-deposited on the anode 3 on which the nano spheres 32 are arranged. In this embodiment, the metal is Au. (e) of FIG. 7 is a cross sectional view illustrating a substrate on which the metal is vapor-deposited in the step of forming the metal nano cluster layer. The metal in a gas state is deposited on a surface of the nano spheres 32, thereby forming the metal film 33. Moreover, part of the metal in the gas state is deposited on the anode 3 in gaps between the nano spheres 32 thus arranged.

(Step of Removing Nanospheres)

Next, the substrate on which the metal film 33 is formed is washed with acetone • isoprophyl alcohol, thereby removing the nano spheres 32. By this, the metal film 33 formed on the nano spheres 33 are also removed at the same time. (f) of FIG. 7 is a cross sectional view illustrating the substrate from which the nano spheres are removed in the step of forming the metal nano cluster layer. The metal deposited on the anode 3 in the gaps between the nano spheres remains on the anode 3 from which the nano spheres has been removed. The metals thus remained becomes the metal nano clusters 12.

(g) of FIG. 7 is a perspective view illustrating the metal nano clusters 12 on the anode. Size and shape of the metal nano clusters thus formed vary depending on the size, arrangement, and arrangement density of the nano spheres. In case where the nano spheres are formed as a two-layered film, the gaps between the nano spheres become smaller, whereby the metal nano clusters are formed on the anode 3 with a smaller density. Moreover, a different shape of the nano clusters is obtained.

(h) of FIG. 7 is a plane view illustrating the substrate, as illustrated in (f) of FIG. 7, on which the metal nano clusters 12 are formed on the anode 3. The metal nano clusters 12 are formed in positions where no nano sphere was present on the anode 3. In the case where the nano spheres are arranged with a high density in the step of performing the metal vapor deposition, the metal nano clusters layer is formed with the metal nano clusters 12 provided dispersedly.

After that, via the steps of forming hole transportation layer etc., an OLED as illustrated in FIG. 6 is obtained.

<Examples of Other Steps>

The step of forming the metal nano clusters is not limited to the user of nano spheres, and may be carried out by vapor deposition with masking, or by lithography.

### Embodiment 3

In the present embodiment, an OLED of a polymer type, which is formed from an organic luminescent material of a polymer type and is provided with metal nano particles on an anode, is described. For the sake of easy explanation, the like members and configurations having the same functions as the member and configuration described in Embodiment 1 are labeled in the same manner as those described in Embodiment 1 and their explanation is not repeated here.

<Configuration of OLED>

FIG. 8 is a cross sectional view illustrating a configuration of an OLED according to the present embodiment. An OLED 13 includes a glass substrate 2, an anode 3 formed on the glass substrate 2, metal nano particles 5 provided dispersedly on the anode 3, a luminescent layer 14 formed on the anode 3 and the metal nano particles 5, and a cathode 9 formed on the luminescent layer 14. The OLED 13 is an organic electroluminescence device configured such that the luminescent layer 14 is formed from an organic luminescent material of a polymer type.

The glass substrate 2 is a substrate on which the OLED 13 is formed, and is a transparent substrate optically transmissive.

The anode 3 is a transparent electrode optically transmissive and electrically conductive. In the present embodiment, the anode 3 is made from ITO. The OLED 13 is a light emitting device, which emits light from an anode 3-side.

The metal nano particles 5 are nano-size metal clusters formed from metal atoms. On the anode 3, the metal nano particles 5 are provided dispersedly with substantially uniform density. It can be considered that the layer in which the metal nano particles 5 are provided dispersedly on the anode 3 is a metal nano particle layer. In the present embodiment, the metal nano particles 5 are spherical Au (gold) nano particles. Each Au nano particle has a diameter of approximately 12 nm. Moreover, the metal nano particles 5 may be preferably formed from gold, silver, copper, or palladium. Spherical metal nano particles made from any of these metals have a later-described surface plasmon resonance frequency in a visible light range. Moreover, because surface plasmon resonance is largely dependent on a magnitude of an imaginary part of a dielectric constant of metal particles, gold and silver are especially preferable as the material from which the metal particles 5 are formed. Beside, noble metals such as platinum, rhodium, iridium, etc., or general metals such as nickel, cobalt, bismuth, etc. can be employed. The diameter of the metal nano particles used herein is preferably in a range of 5 nm to 100 nm. Moreover, the shape of the metal nano particles is not limited to sphere, but may be any shapes such as rectangular shape, rod-like shape, tetrahedral shape, etc. The wavelength range of the light absorbed by the surface plasmon of the metal nano particles is largely dependent on the shape of the metal nano particles. Therefore, the metal nano particle layer having a frequency of the surface plasmon resonance in the visible light range may be formed by using metal nano particles formed from any general metal and having a shape of triangular pyramid, a quadrangular pyramid or the like.

The luminescent layer 14 is made from an organic luminescent material of a polymer type, in which holes and electrons bond together thereby to emit light. In the present embodiment, the luminescent layer 14 is a layer mainly containing polyparaphenylene vinylene (PPV). The luminescent layer 14 has a thickness of about 100 nm. Polyparaphenylene vinylene is excellent in film formability on the anode 3 and the cathode 9, which are made from an inorganic material, and also excellent in the electron transportability and hole transportability. Thus, unlike the luminescent material of the low molecular type, the luminescent layer 14 is employable in the OLED without the need of another layer (that is, a single layer configuration made from the luminescent layer 14 is possible).

Moreover, the luminescent layer may be made from a known luminescent material of a polymer type. For example, the luminescent layer may be made from a luminescent material of a polymer type, such as polyphenylene, polythiophene, a polyfluorene derivative, or polyvinyl carbazole (PVCz), or the like.

The cathode 9 is an electrode made from aluminum in the present embodiment.

Again in the OLED of the polymer type, another layer such as a hole injection layer, a hole transportation layer, or the electron injection layer, etc. may be added. For example, in case where a hole transportation layer is provided in the OLED illustrated in FIG. 8, the hole transportation layer is provided to cover the metal nano particles on the anode, as in Embodiment 1, and then the luminescent layer is provided on the hole transportation layer. The hole transportation layer on the metal nano particles allow the luminescent layer to have more luminescence in a part near an interface between the luminescent layer and the hole transportation layer. Further, the hole transportation layer (having a thickness of 20 nm, for instance) can cause the area in which the more luminescence occurs, and the metal nano particles to be separated from each other by an appropriate distance. This makes it possible to attain the effect of the SPCE more efficiently. Moreover, a hole blocking layer may be provided between the hole transportation layer and the luminescent layer.

Moreover, in case where the hole injection layer is provided in the OLED illustrated in FIG. 8, the metal nano particles are provided on the anode, the hole injection layer is provided to cover the anode and the metal nano particles, and the luminescent layer is provided on the hole injection layer. The hole injection layer may be made from, for example, PEDOT: PSS (poly(3,4-ethylenedioxythiophene)-poly-(styrenesulfonate)), or another material having good hole injectablility. The hole injection layer (having a thickness of 20 nm, for instance) can cause the area in which the more luminescence occurs, and the metal nano particles to be separated from each other by an appropriate distance. This makes it possible to attain the effect of the SPCE more efficiently.

The OLED 13 is configured such that the metal nano particles 5 are dispersedly dispersed in plane between the anode 3 and the luminescent layer 14. The bonding between the holes and electrons injected into the luminescent layer 14 respectively from the anode 3 and the cathode 9 takes place in the whole luminescent layer 14, thereby causing the luminescent layer 14 to perform the luminescence. The surface plasmon of the metal nano particle layer 5 causes resonance with excited electrons injected in the luminescent layer 14 in an area distanced from the metal nano particle layer by about 10 nm to 30 nm. The resonance causes the SPCE. Moreover, the metal nano particles provided on the anode can improve the hole injectability from the anode.

While the ratio of the electrons in the singlet excited state is about 25% with respect to the whole electrons in the organic luminescent material of the low molecular type, this ratio is higher in the organic luminescent material of the polymer type than in the organic luminescent material of the low molecular type. Because the SPCE is luminescence caused by using the energy of the electrons in the singlet excited state, the SPCE due to the metal nano particle layer is more effective in the OLED of the polymer type than in the OLED in the low molecular type. Therefore, the OLED 13 of the present embodiment can attain much greater luminescence luminance than an conventional art.

Moreover, the SPCE can convert into the light the energy of the electrons that are consumed in the form of heat and do not contribute to the luminescence conventionally. Thus, the effect (luminescence reinforcement multiplying factor) of the SPCE due to the metal nano particle layer is greater when an original internal quantum efficiency (internal quantum efficiency without the metal nano particle layer) is lower. The organic luminescent material of the polymer type is more difficult to develop than the organic luminescent material of the low molecule, and does not have a high internal quantum efficiency. Because the effect of the SPCE due to the metal nano particle layer is greater when the internal quantum efficiency is lower (that is, when more electrons whose excitation energy is supposed to be consumed as heat energy are available). For example, the present invention may be applied to dramatically improve luminescence efficiency of a luminescent material excellent in stability (device life) or productivity but poor in luminescence efficiency. Therefore, the present invention provides a technique capable of allowing more varieties of materials to select, and speeding up development of the material of the polymer type, which has been difficult to develop.

<Steps of Manufacturing Organic Light Emitting Element>

A method of manufacturing an OLED according to the present invention mainly includes a step of preparing a particle dispersion liquid containing metal nano particles, a step of forming an anode, a step of forming a binder layer, a step of forming a metal nano particle layer, a step of removing a binder layer, a step of forming a luminescent layer, and a step of forming a cathode. In the following, these steps are described in detail.

<Step of Preparing Particle Dispersion Liquid Containing Metal Nano Particles>

In this step, a particle dispersion liquid containing metal nano particles 5 for forming the metal nano particle layer is prepared. In the present embodiment, the metal is Au. Au nano particles of about 12 nm in diameter are prepared. A particle dispersion liquid in which the Au nano particles are dispersed is used in the present embodiment. The step of preparing the particle dispersion liquid containing metal nano particles is identical with that of Embodiment 1. Thus, its explanation is not repeated here.

<Step of Forming an Anode>

On the glass substrate 2, an ITO film is formed, thereby forming an anode 3, which is a transparent electrode. The Step of forming the anode is identical with that of Embodiment 1.

<Step of Forming a Binder Layer>

In the step of forming a binder layer, the binder layer is formed on the anode 3, in order to make it easier to provide the metal nano particles 5 on the anode 3. In the present embodiment, the binder layer is a single-layered film made from AHAPS. The step of forming the binder layer is identical with that of Embodiment 1.

<Step of Forming Metal Nano Particle Layer>

In the step of forming metal nano particle layer, the metal nano particles 5 are provided on the binder layer by the advective accumulation method. The step of forming the metal nano particle layer is identical with that of Embodiment 1.

<Step of Removing the Binder Layer>

In the step of removing the binder layer, the binder layer on which the metal nano particles have been provided is removed. The binder layer is provided in order to cause the metal nano particles 5 to be provided dispersedly and uniformly. Thus, it is possible to remove the binder layer after the metal nano particles 5 are provided.

In the present embodiment, the removal of the binder layer is carried out by exposing the substrate including the binder layer to an atmospheric He plasma. For example, the binder layer made from organic molecules can be removed by being degraded by using atmospheric He plasma. In case the binder layer is made from AHAPS, the removing process using the atmospheric He plasma causes the metal nano particles 5 dispersedly scattered on the binder layer 4 on the anode 3 to be moved on the anode 3 as dispersedly scattered. That is, the step of removing the binder layer makes it possible to obtain a substrate on which the metal nano particles 5 are dispersedly and uniformly distributed on the anode 3.

The removal of the binder layer may be carried out by another chemical process such as ozone process, or a physical process, depending on the material of the binder layer. It should be noted that the luminescent layer may be provided on the binder layer without removing the binder layer.

<Step of Forming a Luminescent Layer>

In the step of forming the luminescent layer, the luminescent layer 14 is formed on the anode 3 in such a way that the luminescent layer 14 covers the metal nano particles 5 thereon. In the present embodiment, a liquid containing a material (polypara phenylenevinylene in the present embodiment) from which the luminescent layer 14 will be formed is applied on the anode 3 and the metal nano particles 5, in order to form the luminescent layer 14. More specifically, the liquid including the material of the luminescent layer 14 is dropped and spin-coated on the anode 3 and the metal nano particles 5 by spin coating, thereby forming the luminescent layer 14. Note that the luminescent layer may be formed by another well-known method such as injecting or the like.

<Step of Forming a Cathode>

In the step of forming a cathode, the cathode 9 is formed on the luminescent layer 14 by vapor deposition. The cathode 9 may be formed from a material (aluminum in the embodiment) by vacuum vapor deposition as in a conventional art.

In this way, an OLED 13 as illustrated in FIG. 8 is obtained. After that, sealing is performed in order to protect the OLED 13 from atmosphere, humidity, etc.

<Examples of Other Steps>

A step of forming a hole transportation layer may be provided after the step of removing the binder layer and before the step of forming the luminescent layer. In the step of forming the hole transportation layer, a liquid containing a material from which the hole transportation layer will be formed is applied and spin-coated on the anode and the metal nano particles, so as to form the hole transportation layer. The hole transportation layer may have a thickness thick enough to separate the metal nano particles from the luminescent layer with an appropriate distance (for example, about 20 nm), so that the SPCE can be efficiently attained.

Moreover, a step of forming a hole injection layer may be provided after the step of removing the binder layer and before the step of forming the luminescent layer (and before the step of forming the hole transportation layer). In the step of forming the hole injection layer, a liquid containing a material (for example, PEDOT: PSS) from which the hole injection layer will be formed is applied and spin-coated on the anode and the metal nano particles, so as to form the hole injection layer. The hole injection layer may have a thickness thick enough to separate the metal nano particles from the luminescent layer with an appropriate distance (for example, about 20 nm), so that the SPCE can be efficiently attained.

In the steps for manufacturing the OLED of the polymer type according to the present embodiment, the number of steps performed under vacuum and the total number of steps are smaller than in the steps for manufacturing the OLED of the low molecule type in Embodiment 1. Consequently, the OLED of the polymer type according to the present embodiment does not need a large-scale vacuum processing device. Therefore, the OLED of the polymer type according to the present embodiment can be produced at lower cost. Furthermore, because the luminescent layer can be formed by coating, it is easy to provide the OLED of the polymer type according to the present embodiment with a large area.

### Example 1

In the following, the present invention is described in more details, referring to Examples. It should be noted that the present invention is not limited to the Examples. The present Example describes a method for manufacturing an OLED having an Au nano particle layer formed from dispersedly-provided Au nano particles by using a particle dispersion liquid in which the Au particles are dispersed, as in Embodiment 1.

<Preparation of a Particle Dispersion Liquid Containing an Au Nano Particles>

Firstly, Au nano particles were prepared in the present Example. In 0.5 ml of ultrapure water, 5.0 mg of gold chloride trihydrate (Aldrich) was added so as to prepare a gold chloride aqueous solution of 1 mass/volume %. The gold chloride aqueous solution was adjusted to 40 ml in total by further adding ultrapure water thereto. Furthermore, into 2 ml of ultrapure water, 20.0 mg of trisodium citrate (Wako pure chemical Industries Ltd.) was added to prepare a trisodium citrate aqueous solution of 1 mass/volume %. To the trisodium citrate aqueous solution, 25 μl of tannin acid aqueous solution of 1 mass/volume % (Wako pure chemical Industries Ltd.) was added and made up to 10 ml in total by further adding ultrapure water therein, so as to obtain a trisodium citrate-tannin acid mixture aqueous solution.

The gold chloride aqueous solution thus prepared was transferred into a three-necked flask made from silica glass. Then, a reflux condenser was attached to the flask. A 30-ml vial container containing the trisodium citrate-tannin acid mixture aqueous solution thus obtained above was fixed by use of a holder. The gold chloride aqueous solution and the trisodium citrate-tannin acid mixture aqueous solution were respectively put in oil bathes of 60° C., and stirred under heating. The stirring under heating was conducted by using a hot magnet stirrer (RCT basic & ETS-D6, made by IKA). The stirring rate was 250 rpm for both. When the temperatures of the oil bathes were stabilized at 60° C., the trisodium citrate-tannin acid mixture aqueous solution was rapidly added into the gold chloride aqueous solution. After that, the temperature of the oil bath was set to 120° C., and then the gold chloride-trisodium citrate-tannin acid mixture aqueous solution was stirred for 10 min under heating, and then cooled with water to a room temperature under stirring.

After the water-cooling, washing and concentration adjustment of Au nano particles was carried out with ultrapure water. More specifically, the gold chloride-trisodium citrate-tannin acid mixture aqueous solution was diluted with ultrapure water and then centrifuged at 7000 rpm for 20 min so as to precipitate the Au nano particles. Then, a supernatant was decanted by using a micro pipette. The dilution, centrifugation, and decantation were repeated, thereby washing the Au nano particles. From the precipitate, the Au nano particles were measured out by using an electronic scale. By adding ultrapure water to the Au nano particles, an Au nano particle mixture solution of about 20 mass % was prepared. The Au nano particle mixture solution was dispersed ultrasonically for 60 min, thereby obtaining an Au nano particle dispersion liquid.

The Au nano particle dispersion liquid thus obtained was measured as to zeta potential of Au nano particle. The measurement was carried out by using ELS-8000 (Otsuka electronics Co. Ltd.), whose cell was kept to a constant temperature by circulating water of 25° C. around the cell. The cell had been sufficiently washed with ultrapure water running through the cell before the measurement. The measurement was carried out with the Au nano particle dispersion liquid diluted to about 0.1 mass %. The measurement found that the zeta potential of the Au nano particles was −40 mV. The Au nano particle was spherical and about 12 nm in diameter.

In the preparation of the Au nano particles, a higher concentration of the tannin acid gives a smaller diameter of the resultant Au nano particles, and a lower concentration of the tannin acid gives a greater diameter of the resultant Au nano particles. By this method, it is possible to obtain Au nano particles of not less than 5 nm but not more than 30 nm in particle diameter.

By the method for preparing the metal nano particles in a solution as in the present Example, monocrystal metal nano particles can be obtained.

<Preparation of ITO Glass Substrate>

FIG. 9 is a plane view illustrating an OLED prepared in the present Example. A silica glass substrate used as a device substrate was 10 mm×10 mm in size and 1 mm in thickness, and had a luminescence area of 2 mm×2 mm.

In the present Example, a commercially-available ITO glass substrate in which an ITO film is formed on a glass substrate was used. Used as the device substrate was an ITO glass substrate (Furuuchi Chemical Corp.) in which ITO was vapor-deposited on polished glass so as to serve as a transparent electrode used as an anode. The anode made from ITO was 2 mm in width, 10 mm in length, and 200 nm in thickness.

<Formation of Binder Layer>

The device substrate with the anode formed thereon was washed ultrasonically with acetone and isopropyl alcohol for 10 min. Further, the device substrate was heated at 200° C. for 60 min. After that, the device substrate was treated with an UV-03 washing device (Technovision Inc.) for 30 min, so as to remove organic matters on the substrate. The device substrate thus prepared and a mixture solution of 0.1 ml of AHAPS(N-(6-aminohexyl)-3-aminopropyltrimethoxy silane) molecule (Gelest Inc.) and 0.7 ml of toluene (Wako pure chemical Industries Ltd.) were sealed in a container made from PFA (copolymer of tetrafluoroethylene and perfluoroalkylvinyl ether). The device substrate was placed on an upper surface of the container. The container was heated at 100° C. for 60 min by using a desk-top electronic furnace (Nitto Kagaku Co. Ltd.).

After that, the device substrate was taken out of the container and then washed ultrasonically, thereby obtaining a device substrate on which a single layer of AHAPS was formed on a device oxide film. The ultrasonic washing was carried out with toluene, acetone, ethanol, and ultrapure water in this order for 2 and half minutes each. The AHAPS layer was formed over a whole anode-side surface of the device substrate.

A zeta potential of a surface of the AHAPS layer on the device substrate was measured by using ELS-8000 and monitor particles (Otsuka Electronics Co. Ltd.). which was diluted to about 0.1 mass %. A cell of ELS-8000 was kept to a constant temperature by circulating water of 25° C. around the cell. The cell had been sufficiently washed with ultrapure water running through the cell before the measurement. The measurement found that the zeta potential of the surface of the AHAPS layer was +25 mV.

<Formation of Au Nano Particle Layer>

An Au nano particle layer was formed on the AHAPS layer in the following manner. The formation of the Au nano particle layer was carried out by using a horizontally-driven nano coater having the same configuration as illustrated in FIGS. 4 and 5. The horizontally-driven nano coater is capable of forming a nano particle layer on an upper surface of a lower one (lower substrate) of a pair of substrates placed on one another by introducing a particle dispersion liquid into a gap between the pair of substrates and horizontally moving only the lower substrate together with a stage by using a stepping motor to which stage the lower substrate was fixed.

On the stage, the device substrate was placed as the lower one of the substrates in such a way that the AHAPS layer faces upward and the device substrate was fixed to the stage by being sucked from blow by using a sucking chuck. As the upper one of the substrates, a silicone nitride of 30 mm×100 mm in size was placed. The upper one of the pair of substrates has a size of 30 mm along a moving direction of the lower substrate. A levelness of an upper surface of the stage to which the lower substrate was fixed was adjusted roughly within ±3 μm by using an electric micrometer and a declining stage, and then was adjusted by using an electrostatic capacitance-type displacement gauge so as to attain a levelness of 600 nm or less when the lower one of the pair of substrate was horizontally moved by 60 mm. The gap between the pair of substrates was distanced by 30 μm at an edge at which the Au nano particle layer was formed (edge located in a forward direction in the moving direction of the lower substrate), and 60 μm at an edge opposite to the edge by using a thickness gauge and Z-axis stage (Sigma Koki Co. Ltd.). An angle of inclination of the upper one of the pair of substrates was measured by using micro meter head (Mitsutoyo Corp.).

On the lower substrate, the Au nano particle dispersion liquid of 20 mass % obtained in the preparation of the particle dispersion liquid containing the Au nano particles was dropped by 70 μl. After that, the upper one (upper substrate) of the pair of substrates was fixed at a predetermined position, and the Au nano particle dispersion liquid was sealed between the pair of substrates. The lower substrate was horizontally moved at a rage of 1.0 mm/sec by the stepping motor, so as to form an Au nano particle layer dispersedly provided.

As described in the above Embodiments, a probe of an electrostatic capacitance meter was placed at an edge of the upper one of the pair of substrates in such a way that the probe overlaps a meniscus portion of the Au nano particle dispersion liquid. The moving rate of the lower substrate moved by the stepping motor was adjusted, so that the electrostatic capacitance thus measured was kept within a predetermined range. The measurement of the electrostatic capacitance was carried out every 0.005 sec. Every time the electrostatic capacitance was measured, the moving rage of the lower substrate was adjusted based on the electrostatic capacitance thus measured. By adjusting the moving speed of the lower substrate in such a way, it was possible to bring the electrostatic capacitance to the predetermined range substantially within 0.1 sec, even if the electrostatic capacitance went out of the predetermined range. That is, by adjusting the substrate moving speed, the concentration of the Au nano particles in the meniscus portion can be kept constant. This makes it possible to provide the Au nano particles on the AHAPS layer dispersedly, highly densely, and uniformly. Note that the step of forming the metal nano particle layer was carried out at room temperatures.

The Au nano particle layer was formed all over the surface of the device substrate. The density of the Au nano particles was measured at plural points on the device substrate. It was found that the density in 1 pmt was substantially constant and was about 10 particles/pmt.

(a) of FIG. 10 is an image of the ITO film of the device substrate pictured by using an Atomic Force Microscope (AFM). (b) of FIG. 10 is an image of the Au nano particles on the AHAPS layer by AFM, which AHAPS layer was formed on the ITO film of the device substrate. In the image, the black points indicate low heights whereas white pointes indicate high heights. In (b) of FIG. 10, the white particles are individual Au nano particles. The Au nano particles were provided separately from each other. For example, if two Au nano particles contact with each other, greater SPCE can be attained than in case where the Au nano particles are separated from each other. Thus, it is no problem that the Au nano particles are in contact with each other on the device substrate. However, in order to produce the OLED with stable properties, it is preferable that the Au nano particles are distributed with constant density.

FIG. 11 is a graph plotting absorbency of the device substrate illustrated in (a) of FIG. 10 in which the ITO film was formed on the glass substrate, and absorbency of the device substrate as illustrated in (b) of FIG. 10 in which the Au nano particles were provided on the AHAPS layer. The horizontal axis of the graph in FIG. 11 indicates a wavelength of light, and a vertical axis thereof indicates absorbency. The device substrate on which the ITO film was formed had absorbency substantially constant in the visible light range. The absorbency of the device substrate was about 0.019, that is, transparency of the device substrate was about 0.96. The device substrate on which the Au nano particles had an absorbency peak in the vicinity of the wavelength of 520 nm, which is close to 540 nm, which is the wavelength the fluorescent luminescence of Alq₃ from which the luminescent layer was formed. The Au nano particles absorbs light in the wavelength range (about 460 nm to 580 nm) within which the absorbency peak exists. Thus, the device substrate on which the Au nano particles are provided is capable of exciting surface plasmon-inducing reinforcement in the luminescence by the surface plasmon in the fluorescent material emitting light within the wavelength range. The fluorescent luminescence of the Alq₃ also has a wavelength range peaked at 540 nm. The device substrate on which the Au nano particles were provided had an absorbency of about 0.036 at a wavelength at which the absorbency peak was highest. That is, the device substrate had transparency of about 0.92 at this wavelength. Thus, the light emitted from the luminescence layer is not blocked substantially by the device substrate on which the Au nano particles were provided. Thus, the device substrate allows the light emitted from the luminescence layer to pass through the device substrate. That is, it was proved that even though the device substrate is configured such that the metal nano particles are provided on the anode, which is a transparent electrode, the device substrate showed high transparency because the metal nano particles were distributed in the form of a single layer dispersedly and each metal nano particle was small. Therefore, the OLED in which the metal nano particles are formed on the anode can be sufficiently effective in reinforcing the luminescence by surface plasmon.

<Formation of Hole Transportation Layer>

The formation of the organic film and the cathode is briefly described below, because it can be carried out by a well-known technique.

The device substrate on which the metal nano particles were provided was placed in a vacuum chamber, so that copper phthalocyanine (CuPc) was vapor-deposited thermally so as to form a hole transportation layer thereon. Vapor deposition rate of copper phthalocyanine was 0.01 nm/s and a thickness of the hole transportation layer thus formed was about 20 nm. Pressure inside vacuum chamber was reduced to 1.0×10⁻⁴ Pa.

<Formation of Luminescent Layer>

Next, on the device substrate on which the hole transportation layer was formed, Tris(8-hydroxyquinolinato)aluminum(III) complex (Alq₃) was vapor-deposited thermally so as to form a luminescent layer. Vapor deposition rate of Alq₃ was 0.01 nm/s and a thickness of the luminescent layer thus formed as about 100 nm. Alq₃ was to function as both the luminescent layer and the electron transportation layer.

<Formation of Electron Injection Layer>

Next, on the device substrate on which the luminescent layer was formed, lithium fluoride (LiF) was vapor-deposited thermally so as to form an electron injection layer. Vapor deposition rate of LiF was 0.01 nm/s, and a thickness of the electron injection layer thus formed was about 0.5 nm.

<Formation of Cathode>

Next, on the device substrate on which the electron injection layer was formed, aluminum (Al) was vapor-deposited thermally so as to form a cathode.

In this way, an OLED including an Au nano particle layer and having a light emitting area of 2 mm×2 mm in size as illustrated in FIG. 9 was prepared.

<Characteristics Analysis Results>

The OLED including the Au nano particle layer was measured as to its voltage-current density (V-I) characteristics, and current density-luminescence intensity (I-L) characteristics. (a) of FIG. 12 is a graph illustrating the voltage-current density (V-I) characteristics of the OLED (SPCE-EL) including the Au nano particle layer. The horizontal axis indicates a voltage (V) applied between the anode and the cathode of the OLED. The vertical axis indicates the current density (mA/cm²). The applied voltage was changed from 0 V to 15 V. In (a) of FIG. 12, a control is also plotted, which is a voltage-current density (V-I) of a conventional OLED (N-EL) prepared with the same conditions except that conventional OLED did not include an Au nano particle layer (and the binder layer). As illustrated in (a) of FIG. 12, the OLED including the Au nano particle layer according to the present Example showed a substantially same voltage-current density (V-I), compared with the conventional OLED including no Au nano particle layer.

(b) of FIG. 12 is a graph illustrating the current density-luminescence intensity (I-L) of the OLED (SPCE-EL) including the Au nano particle layer. The horizontal axis indicates a current density (mA/cm²) of current flowing through the OLED, and the vertical axis indicates luminescence intensity (cd/m²). The luminescence intensity of the OLED is luminance measured at a position distanced from a light emitting surface of the OLED by a certain distance, and a relative value for comparison. In (b) of FIG. 12, a control is also plotted, which is a current density-luminescence intensity (I-L) of a conventional OLED (N-EL) prepared with the same conditions except that conventional OLED did not include an Au nano particle layer (and the binder layer). (b) of FIG. 12 plots the relationship between the current density and the luminance intensity against the change in the applied voltage from 0 V to 15 V for both the OLED of the present Example and the conventional OLED. For example, when the applied voltage was 15 V, the OLED according to the present Example had a current density of 5.7 mA/cm² and a luminescence intensity 0.69 cd/m² meanwhile, the conventional OLED had a current density of 7.6 mA/cm² and a luminescence intensity 0.045 cd/m². That is, when the applied voltage was 15 V, the OLED including the Au nano particle layer was improved in luminescence intensity by about 15 times. As to luminescence efficiency (luminescence intensity per current density) with the same applied voltage (15 V), the OLED according to the present Example was about 20 times greater than the conventional OLED. That is, the introduction of the Au nano particle layer improved the luminescence efficiency by about 20 times with the same applied voltage. As such, the Au nano particle layer formed on the anode can significantly reinforce the luminescence intensity and luminescence efficiency of an OLED. Moreover, the OLED including the Au nano particle layer according to the present Examples requires a current of a smaller ampere value in order to attain the same luminance, thereby resulting in longer life of the OLED.

### Example 2

The present Example describes a method for manufacturing an OLED having an Au nano particle layer, from which OLED a binder layer had been removed. The method is identical to that of Example 1 until the formation of the Au nano particle layer on the binder layer. In the present Example, the binder layer (AHAPS layer) was removed after the formation of the Au nano particle layer.

<Removal of Binder Layer>

The AHAPS layer was removed from a devices substrate on which the AU nano particle layer was formed on the AHAPS layer. The removal of the AHAPS layer was carried out by using He plasma by using an atmospheric plasma processing device. The atmospheric plasma processing device is configured to supply a high-frequency electricity of 13.56 MHz so as to generate a high-frequency plasma locally in a space in atmospheric environment. The atmospheric plasma processing device had electrodes, which each was a copper pipe of 3 mm in outer diameter, covered with an alumina tube of 5 mm in inner diameter.

The device substrate was subjected to surface plasma treatment in the following manner. The device substrate was placed on a sample stage in a vacuum chamber and sealed therein. Pressure inside the vacuum chamber was reduced to 2.0×10⁻¹ torr by a rotary pump. And then helium gas was introduced into the vacuum chamber until the pressure was increased to 760 torr. At the same time as the high-frequency electricity was supplied, the scanning stage on which the device substrate was placed was moved, whereby the whole upper surface of the device substrate was subjected to the plasma treatment. Right after the plasma treatment was completed, the supply of the high-frequency electricity was stopped. Then, the vacuum chamber was opened to take the device substrate out of the vacuum chamber. The electricity supplied was set to 15 W and the electrode was distanced from the device substrate by 2.5 mm. The plasma was maintained for 15 sec at each point on the device substrate.

After the AHAPS layer serving as the binder layer was removed as described above, a hole transportation layer, a luminescent layer, an electron injection layer, and a cathode were formed on the Au nano particle layer in the same way as in Example 1. A resultant OLED including the AU nano particle layer had voltage-current density (V-I) characteristics and current density-luminescence intensity (I-L) characteristics substantially identical with that of the OLED of Example 1, which included the Au nano particle layer and the binder layer.

### Example 3

The present Example described a method for manufacturing an OLED having an Au nano cluster layer described in Embodiment 2. The method is identical to that of Example 1 until the preparation of an ITO glass substrate. In the present Example, a method for manufacturing an OLED having an Au nano cluster configuration, in which nano spheres were used.

<Formation of Nano Sphere>

The ITO glass substrate used herein was identical with the one used in Example 1. The device substrate provided with an anode made from ITO was washed with acetone • isopropyl alcohol (IPA).

Nano spheres made from polystyrene and being about 200 nm in diameter were mixed in a solvent of ethanol of 300 μL, thereby forming a nano sphere mixture solution. The nano sphere mixture solution had a nano sphere concentration of 0.3 mass % with respect to the solvent. The nano spheres can be prepared by using a well-known technique (see Non-Patent Literature 4).

On the anode of the device substrate thus washed, the nano sphere mixture solution of 10 μl was dropped. Then, the device substrate was naturally dried to evaporate the solvent off. As a result, a device substrate on which the nano spheres were densely arranged on the anode was prepared.

<Au Vapor Deposition>

Next, the device substrate was placed in the vacuum chamber and subjected to Au vapor deposition to thermally vapor-deposit Au on the anode on which the nano spheres were arranged. The Au vapor deposition was carried out for 30 sec, so as to form an Au film of about 20 to 25 nm in thickness.

<Removal of Nano Spheres>

Next, the substrate on which the Au film was formed on the nano spheres was washed with acetone • isopropyl alcohol, so that the nano spheres were removed from the substrate. By this, the Au film formed on the nano spheres were also removed at the same time, thereby consequently remaining Au deposited on the anode in gaps between the nano spheres. In this way, a substrate on which the Au nano clusters formed dispersedly on the anode was obtained.

(a) of FIG. 13 is an atom force microscopic image of the substrate from which nanospheres were removed. (b) of FIG. 13 is a magnified image of Area A shown in (a) of FIG. 13. In the images, the darker points are lower in height and the brighter points the higher in height. The Au nano clusters are formed where the images look white. The apparently aligned black circles are places where the nano spheres were provided. It can be seen that Au was not deposited in the places. The Au clusters were formed dispersedly around the black circles. However, the production does not allow the nano spheres to exist without gaps. Thus, Au was formed connectively in a long string shape in some places.

FIG. 14 is a graph illustrating height of a device surface across a certain cross section (e.g., line B) of (b) of FIG. 13. One Au nano cluster was about 20 nm to 25 nm in height, and has a bottom surface width of about 100 nm to 200 nm.

After that, a hole transportation layer, a luminescent layer, an electron injection layer, and a cathode were formed on the Au nano particle layer in the same way as in Example 1. A resultant OLED including the AU nano cluster layer had voltage-current density (V-I) characteristics and current density-luminescence intensity (I-L) characteristics substantially identical with that of the OLED of Example 1, which included the Au nano particle layer and the binder layer.

There is a difficulty in producing the Au nano clusters with uniform density distribution, so that every OLED is different as to how much Au was connectively formed in the string shapes. Therefore, the OLED of Example 1 or 2 including the Au nano particle layer is more stable in property.

### Example 4

The present Example describes a method for manufacturing an OLED having an Au nano rod layer in which rod-shaped Au nano rods were used instead of the spherical Au nano particles. In the present Example, an Alq₃ layer was provided as an electron transportation layer, and a layer in which Alq₃ was doped with DCM was formed as a luminescent layer. In the present Example, the Au nano rod layer causes red-color SPCE.

<Preparation of Particle Dispersion Liquid Containing Au Nano Rod>

Firstly, Au nano rod was prepared in the present Example. Into 5 ml of Hexadecyl trimethyl ammonium bromide (CTAB) aqueous solution (concentration: 0.2 mol/l), 5 ml of chlorauric acid (III) (HAuCl4) (concentration: 5.0×10⁻⁴ mol/l) was added and stirred. In a resultant solution, 0.6 ml of a sodium borohydride (NaBH₄) aqueous solution (concentration: 1.0×10⁻² mol/l) cooled to about 4° C. was added and then stirred for 2 min. Thereby, a seed solution was prepared. The seed was stored at about 30° C.

Into 0.25 ml of silver nitrate (AgNO₃) aqueous solution (concentration: 4.0×10⁻³ mol/l), 5 ml of CTAB aqueous solution (concentration: 0.2 mol/l) was added and stirred. Into a resultant solution, 5 ml of chlorauric acid (III) aqueous solution (concentration: 1.0×10⁻³ mol/l) was added and stirred. Then, 70 ml of ascorbic acid (AA) aqueous solution (concentration: 7.8810⁻² mol/l). Thereby, a stock solution was prepared.

Into the stock solution, 12 ml of the seed solution was added and stirred. Then, a resultant mixture was kept at about 30° C. About 20 min later, reaction finished, thereby obtaining a solution containing Au nano rods. The preparation of the Au nano rods can be carried out by a well known technique (see Non-Patent Literature 5).

The same process as in Example 1 was carried out with the Au nano rods thus prepared. Thereby, an Au nano rod dispersion liquid in which the Au nano rods were dispersed was obtained.

FIG. 15 was an image of the thus prepared Au nano rods pictured by using a Scanning Electron Microscope (SEM). The Au nano rods thus obtained were Au nano particles (metal clusters) having a bar (rod)-like shape (aspect ratio: 3) of a size of about 20 nm×60 nm×20 nm. The longitudinal length of the Au nano rods thus obtained can be adjusted by adjusting the concentration of the silver nitrate aqueous solution for controlling crystal growth or the concentration of the ascorbic acid aqueous solution serving as a reducing agent, which are used for preparing the stock solution in the preparation of the Au nano rods.

<Formation of Au Nano Rod Layer>

The preparation of the ITO glass substrate and the formation of the binder layer are identical with those in Example 1. After that, the same advective accumulation method as in Example 1 was conducted with the Au nano rod dispersion liquid instead of the Au nano particle dispersion liquid. Thereby, an Au nano rode layer was formed, in which the Au nano rods were provided dispersedly on the binder layer.

After the formation of the Au nano rod layer, the binder layer was removed by the same step as in Example 2.

<Formation of Hole Transportation Layer>

The device substrate on which the Au nano rods were provided was placed in a vacuum chamber. Copper phthalocyanine (CuPc) was thermally vapor-deposited on the device substrate so as to form a hole transportation layer thereon. Vapor deposition rate of copper phthalocyanine was 0.02 nm/s and a thickness of the hole transportation layer thus formed was about 20 nm. Pressure inside the vacuum chamber was reduced to 1.0×10⁻⁴ Pa.

<Formation of Luminescent Layer>

Next, on the device substrate on which the hole transportation layer was formed, Tris(8-hydroxyquinolinato)aluminum(III) complex (Alq₃) and 4-(Dicyanomethylene)-2-methyl-6-(4-dimethylaminostyryl)-4H-pyran (DCM) were vapor deposited at the same time. Film formation rate was 0.08 nm/s for Alq₃ and 0.01 nm/s for DCM. Therefore the film formation was conducted with total film formation rate of 0.09 nm/s. The luminescent layer thus formed was an organic film of Alq₃ containing DCM dopants, and had a thickness of about 60 nm.

<Formation of Electron Transportation Layer>

Next, on the device substrate on which the luminescent layer was formed, Alq₃ was thermally vapor-deposited so as to form an electron transportation layer. Vapor deposition rate of Alq₃ was 0.04 nm/s and a thickness of the electron transportation layer thus formed was about 40 nm. In the organic light emitting element in the present Example, the layer of Alq₃ functioned as an electron transportation layer.

<Formation of Electron Injection Layer>

Next, on the device substrate on which the electron transportation layer was formed, lithium fluoride (LiF) was thermally vapor-deposited, so as to form an electron injection layer. Vapor deposition rate of LiF was 0.01 nm/s, and a thickness of the electron injection layer thus formed was about 0.5 nm.

<Formation of Cathode>

Next, on the device substrate on which the electron injection layer was formed, aluminum (Al) was thermally vapor-deposited, so as to form a cathode.

In this way, an OLED including the Au nano rod layer was obtained.

<Configuration of OLED and Characteristic Analysis Result>

FIG. 16 is a cross sectional view schematically illustrating a configuration of the OLED including the Au nano rod layer, thus obtained via the steps described above. The OLED 15 includes the glass substrate 2, the anode 3 formed on the glass substrate 2 and made from ITO, the Au nano rods 16 provided dispersedly on the anode 3, the hole transportation layer 6 formed on the anode 3 and the Au nano rods 16 and made from copper phthalocyanine, the luminescent layer 7 formed on the hole transportation 6 and made from Alq₃ containing DCM dopants, the electron transportation layer 17 formed on the luminescent layer 7 and made from Alq₃, the electron injection layer 8 formed on the electron transportation layer 17 and made from lithium fluoride, and the cathode 9 formed on the electron injection layer 8 and made from aluminum.

In the OLED of Example 1, the luminescent layer (Alq₃) had a luminescence spectrum peak at a wavelength of about 540 nm, and the Au nano particle layer had an absorbent spectrum peak around the wavelength of 520 nm, which is close to 540 nm. Thus, the luminescent layer emits green light and the Au nano particle layer mainly reinforces the green luminescence by the surface plasmon in Example 1.

On the other hand, in the OLED 15 of the present Example, the luminescent layer (Alq₃+DCM) 7 had a luminescence spectrum peak at a wavelength of about 650 nm due to the dopant (DCM), and the Au nano particle layer had an absorbent spectrum peak at the wavelength of about 650 nm likewise. FIG. 17 is a graph illustrating the absorption spectrum of the Au nano rod dispersion liquid and the luminescence spectrum of the light emitting molecules (DCM) in the luminescent layer in the present Example. Note that the horizontal axis of the graph in FIG. 17 indicates the wavelength of light, and the vertical axis indicates the absorbency (arbitrary unit a. u.) and luminescence intensity (arbitrary unit a. u.). It can be understand from the graph that the luminescence wavelength of the light emitting molecules (DCM) contained in the luminescent layer 7 is in good conformity with the absorbency wavelength of the Au nano rods, that is, the wavelength at which the SPCE occurred. Therefore, the OLED in the present Example is such that the luminescent layer 7 emits red light and the Au nano rod layer mainly reinforces the red luminescence by the surface plasmon. As such, the metal nano particles change their absorption spectrum largely, depending on their shapes (sphere, rod, polyhedron, etc.). That is, the resonance wavelength of the surface plasmon is largely dependent on the shape of the metal nano particles. In case of the metal nano rods, the longitudinal length thereof is also a factor of changing the resonance wavelength of the surface plasmon.

Current density-luminescence intensity (I-L) characteristics of the OLED 15 including the Au nano rod layer were measured. FIG. 18 was a graph illustrating the current density-luminescence intensity (I-L) characteristics of the OLED (Au-EL) including the Au nano rod layer in the present Example. The horizontal axis indicates the current density (mA/cm²) of a current flowing the OLED 15. The vertical axis indicates the luminescence intensity (cd/m²) of the OLED 15. The luminescence intensity of the OLED is luminance measured at a position distanced from a light emitting surface of the OLED by a certain distance, and a relative value for comparison. In FIG. 18, a control is also plotted, which is a current density-luminescence intensity (I-L) of a conventional OLED (N-EL) prepared with the same conditions as the OLED 15 of the present Example except that conventional OLED did not include an Au nano rod layer. The OLED (Au-EL) 15 of the present Example and the conventional OLED (N-EL) were compared in terms of the luminescence efficiency (luminescence intensity per current density) at the applied voltage of 12 V. The OLED 15 of the present Example was about 2.5 in luminescence efficiency than the conventional OLED. That is, the introduction of the Au nano rod layer improves the luminescence efficiency by about 2.5 times with same voltage. As such, the Au nano rod layer formed on the anode can significantly reinforce the luminescence intensity and luminescence efficiency of an OLED. Moreover, the OLED including the Au nano rod layer according to the present Example requires a current of a smaller ampere value in order to attain the same luminance, thereby resulting in longer life of the OLED.

FIG. 19 is a graph illustrating luminescence spectral of the OLED (Au-EL) of the present Example including the Au nano rod layer, and the conventional OLED (N-EL) including the Au nano rod layer. In the graph of FIG. 11, the horizontal axis indicates the wavelength of light and the vertical axis indicates the luminescence intensity (arbitrary unit a.u.). The conventional OLED (N-EL) was prepared identically with the OLED 15, except that the conventional OLED did not have the Au nano rod layer. The OLED (Au-EL) including the Au nano rod layer and the OLED including no Au nano rod layer had substantially identical luminescence spectral. That is, considering this result together with the result illustrated in FIG. 18, it can be understood that the Au nano rods reinforced the red light around the wavelength of 650 nm.

By using the metal nano particles which are Au nano rods whose dimension (longitudinal length) was adjusted as in the present Example, it is possible to obtain an OLED capable of effectively reinforcing luminescence of various wavelength by the surface plasmon.

[Other Modifications]

In order to attain the object, an organic electroluminescence device according to the present invention is an organic electroluminescence device including a luminescent layer between an anode and a cathode, the luminescent layer containing an organic luminescent material, the organic electroluminescence device comprising: a hole transportation layer formed between the anode and the luminescent layer; a metal cluster layer between the anode and the hole transportation layer, the metal cluster layer being a layer in which metal clusters are dispersedly distributed, the metal cluster layer being such that gaps between the metal clusters dispersedly distributed are filled with a hole transportation material.

The metal clusters have an excitation mode by surface plasmon. The surface plasmon of the metal clusters interact with excited electrons in the organic luminescent material of the luminescent layer, thereby reinforcing the luminescence, namely the metal clusters cause SPCE thereof.

With this configuration, the metal clusters dispersedly distributed in the metal cluster layer undergo surface plasmon resonance with the excited electrons in the organic luminescent material of the luminescent layer, thereby reinforcing the luminescence. This can increase luminescence intensity of the organic electroluminescence device.

Moreover, in the luminescent layer, the luminescence due to bonding between electrons and holes takes place mainly in a part near an interface between the luminescent layer and the hole transportation layer. Moreover, the SPCE due to the metal clusters is most effective at a place distanced from the surface of the metal clusters by a certain distance.

This configuration allows the organic electroluminescence device to more effectively reinforce the light emission by the surface plasmon, because the hole transportation layer thus formed separates the surface of the metal clusters and the luminescent layer by the distance suitable for the SPCE. Moreover, the gaps between the metal clusters dispersedly distributed in the metal cluster layer are filled with the hole transportation material. This avoids a decrease in hole transportability and an increase electric resistance in the organic electroluminescence device.

Moreover, the conventional organic electroluminescence device whose luminescence intensity is reinforce by using phosphorescent light is disadvantageous that long relaxing time of the phosphorescent light leads to long excitation period, and consequently high reactivity, thereby likely breaking down the molecules constituting the luminescent layer.

The above configuration can reinforce the luminescence intensity of an organic electroluminescence device without using phosphorescent light. Thus, this configuration can provide the organic electroluminescence device with greater luminescence intensity, a longer life, and lower production cost at the same time.

The organic electroluminescence device may be configured such that the metal clusters are distributed on the anode.

The organic electroluminescence device may be configured such that the hole transportation layer is made from the hole transportation material.

It is preferable in the organic electroluminescence device that the metal clusters have a plasmon resonance wavelength range, which overlaps with wavelength range of luminescence of the luminescent layer. It is more preferable in the organic electroluminescence device that a peak wavelength of the plasmon resonance of the metal clusters substantially matches with a peak wavelength of the luminescence of the luminescent layer.

The organic electroluminescence device may be configured such that the anode is transparent to the light emitted from the luminescent layer.

In an organic electroluminescence device of the bottom emission type, in which the light of the luminescent layer is emitted outside via the anode being transparent, it is not possible to provide anything blocking the light on the anode side. The metal clusters in the above configuration, however, are dispersedly distributed and therefore can allow the light of the luminescent layer to pass therethrough. Thus, the use of the metal clusters can increase the luminescence intensity of the organic electroluminescence device of the bottom emission type.

The organic electroluminescence device may be configured such that the metal clusters are metal particles.

The use of the advective accumulation method makes it possible to form the metal cluster layer by dispersedly providing the metal particles. Thus, the above configuration can be applied to an organic electroluminescence device of the polymer type, which is manufactured by coating.

The organic electroluminescence device may be configured such that the metal clusters are rod-like shaped metal particles.

By adjusting the length of the rod-like shaped metal particles, it is possible to adjust the wavelength of the light, with which the surface plasmon resonance is caused. Thereby, it is possible to reinforce light of a desired wavelength by the surface plasmon.

The organic electroluminescence device may be configured such that the metal clusters absorb light of a wavelength at which the luminescent layer performs luminescence.

The organic electroluminescence device may be configured such that the metal clusters contained in the metal cluster layer include plural types of metal clusters different in shape.

Metal clusters with different shapes absorb light of different wavelengths. That is, metal clusters with different shapes excite surface plasmon resonance for different wavelengths of light. Hence, this configuration can excite surface plasmon resonance for plural wavelengths of light, thereby reinforcing the light of the wavelengths. In case the luminescent layer contains plural types of organic luminescent materials for emitting light of different wavelengths (or the luminescent layer contains an organic luminescent material for emitting light of plural wavelengths), this configuration makes it possible to reinforce the luminescence of the plural wavelengths by surface plasmon.

The organic electroluminescence device may be configured such that the metal clusters contained in the metal cluster layer include plural types of metal clusters made from different metals.

Metal clusters made from different metals absorbs light of different wavelengths. That is, metal clusters made from different metals excite surface plasmon resonance for different wavelengths of light. Thus, this configuration makes it possible to reinforce the luminescence of the plural wavelengths by surface plasmon.

The organic electroluminescence device may be configured such that the metal clusters contains Au as their main component.

Au is low in reactivity and therefore stable. Au exists in the organic electroluminescence device stably. Therefore, the organic electroluminescence device including such metal clusters can endure a long-term usage.

A method according to the present invention for manufacturing an organic electroluminescence device including a luminescent layer between an anode and a cathode, the luminescent layer containing an organic luminescent material is a method comprising: filling a particle dispersion liquid between the anode and a counter member placed to the anode, the particle dispersion liquid in which metal particles are dispersed; providing the metal particles on the anode dispersedly by (i) moving the counter member relatively to the anode in a direction along a surface of the anode, so as to form a meniscus portion of the particle dispersion liquid in a region on the surface of the anode, which region is exposed from the counter member, and by (ii) evaporating a solvent of the particle dispersion liquid; and forming a hole transportation layer so as to fill gaps between the metal particles provided dispersedly and to form the hole transportation layer to cover the metal particles.

With this configuration, the particle dispersion liquid is filled between the anode and the counter member. By changing the positions of the anode and the counter member relatively to each other, an area on the anode is exposed from the counter member and a meniscus portion of the particle dispersion liquid is formed in the exposed area. Here, the meniscus portion of the particle dispersion liquid is a liquid film formed from the particle dispersion liquid due to surface tension of the particle dispersion liquid, the meniscus portion being formed in the area on the anode, which area is exposed from the counter substrate. The solvent of the dispersion liquid is evaporated mainly in the meniscus portion exposed from the counter member. Thus, the particle dispersion liquid is hardly influenced by a temperature change and a humidity change in working environment, thereby making it easier to keep the particle concentration constant in the meniscus portion. Moreover, the area on the anode, in which area the meniscus portion is formed, is defined by the counter member. Thus, it is possible to stabilize where to form the meniscus portion on the anode. Hence, it is possible to provided the metal particles of the particle dispersion liquid on anodes over a wide area (that is, a practical substrate side) uniformly and dispersedly.

Moreover, the method of the present invention is arranged such that the metal particles are provided not by vapor phase epitaxy of metal as in lithography, but by evaporating, in the meniscus portion, the solvent of the liquid in which the metal particles are dispersed. This arrangement provides very high utilization efficiency of the metal raw material. Moreover, the method of the present invention is small in the number of steps and does not require vacuum process. Thus, the method of the present invention just needs small-scale equipment and facility. This lowers the production cost of the organic electroluminescence device. Moreover, the present invention is suitably applicable to organic electroluminescence device of a polymer type, which is manufactured by coating method.

This arrangement allows the organic electroluminescence device to more effectively reinforce the light mission by the surface plasmon, because the hole transportation layer thus formed separates the surface of the metal clusters and the luminescent layer by the distance suitable for the SPCE.

The method may further comprise, before the step of filling: forming a binder layer to which the metal particles are more easily attached than to the anode.

With this configuration, it is possible to provide the metal particles efficiently, thereby attaining uniform distribution of the metal particles.

The method may further comprise, after the step of providing the metal particles and before the step of forming the hole transportation layer: removing the binder layer.

The binder layer is not necessary after the metal particles are provided. Meanwhile, the binder layer would lead to a risk of deteriorating quality of the organic electroluminescence device. With this configuration, after the metal particles are provided on the anode, the binder layer can be removed by for example plasma process or the like, without disturbing the distribution of the metal particles. Thus, it is possible to remove the binder layer, which is now unnecessary or is better to be removed for the sake of the organic electroluminescence device. This can give the organic electroluminescence device a longer life.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

The present invention is applicable to an organic light emitting device containing an organic luminescent material.

### REFERENCE SIGNS LIST

1, 11, 13, 15: Organic light emitting device (organic electroluminescence device)
2: Glass substrate (substrate)
3: Anode
4: Binder layer
5: Metal nano particles (metal clusters, metal particles)
6: Hole transportation layer
7: 14: Luminescent layer
8: Electron injection layer
9: Cathode
12: Metal nano cluster (metal cluster)
16: Au nano rod (metal clusters, metal particles)
17: Electron transportation layer
20: Particle layer forming device
21: First substrate
22: Second substrate (counter member)
23: Particle dispersion liquid
24: Meniscus portion
25: Substrate moving device
26: Particle concentration measuring device (physical amount measuring device)
27: Particle concentration adjusting device
29: Substrate positioning member
30: Nano sphere mixture liquid
31: Solvent
32: Nano sphere
33: Metal film

1. An organic electroluminescence device including a luminescent layer between an anode and a cathode, the luminescent layer containing an organic luminescent material, the organic electroluminescence device comprising:
a hole transportation layer formed between the anode and the luminescent layer;
a metal nano particle layer, between the anode and the hole transportation layer, the metal nano particle layer being a mono-particle layer in which Au nano particles are dispersedly distributed on the anode,
the metal nano particle layer being such that the Au nano particles are distributed separated from each other and gaps between the Au nano particles are filled with a hole transportation material.

2. (canceled)

3. The organic electroluminescence device as set forth in claim 1, wherein the hole transportation layer is made from the hole transportation material.

4. The organic electroluminescence device as set forth in claim 1, wherein the Au nano particles have a plasmon resonance wavelength range, which overlaps with wavelength range of luminescence of the luminescent layer.

5. The organic electroluminescence device as set forth in claim 1, wherein the anode is transparent to the light emitted from the luminescent layer.

6. (canceled)

7. The organic electroluminescence device as set forth in claim 1, wherein the Au nano particles are rod-like shaped particles.

8. The organic electroluminescence device as set forth in claim 1, wherein the Au nano particles absorb light of a wavelength at which the luminescent layer performs luminescence.

9. The organic electroluminescence device as set forth in claim 1, wherein the Au nano particles contained in the metal nano particle layer include plural types of Au nano particles different in shape.

10. (canceled)

11. (canceled)

12. A method for manufacturing an organic electroluminescence device including a luminescent layer between an anode and a cathode, the luminescent layer containing an organic luminescent material, the method comprising:
filling a particle dispersion liquid between the anode and a counter member placed to the anode, the particle dispersion liquid in which metal particles are dispersed;
providing the metal particles on the anode dispersedly by (i) moving the counter member relatively to the anode in a direction along a surface of the anode, so as to form a meniscus portion of the particle dispersion liquid in a region on the surface of the anode, which region is exposed from the counter member, and by (ii) evaporating a solvent of the particle dispersion liquid; and
forming a hole transportation layer so as to fill gaps between the metal particles provided dispersedly and to form the hole transportation layer to cover the metal particles.

13. The method as set forth in claim 9, further comprising, before the step of filling:
forming a binder layer to which the metal particles are more easily attached than to the anode.

14. The method as set forth in claim 10, further comprising, after the step of providing the metal particles and before the step of forming the hole transportation layer:
removing the binder layer.

15. The organic electroluminescence device as set forth claim 3, wherein the Au nano particles are such that the Au nano particles cause surface plasmon coupled emission by causing plasmon resonance with light of a wavelength emitted from the luminescent layer.

16. The method as set forth in claim 9, wherein:
the metal particles have a plasmon resonance wavelength range, which overlaps with wavelength range of luminescence of the luminescent layer; and
the metal clusters are such that the metals clusters cause surface plasmon coupled emission by causing plasmon resonance with light of a wavelength emitted from the luminescent layer.
